(19) United States
(12) Patent Application Publication
(10) Pub. No.: US 2026/0023902 A1
(43) Pub. Date: Jan. 22, 2026

(54) INTEGRATED PLATFORM AND METHOD FOR OPTIMIZING AN ELECTROMAGNETIC PUMP

(71) Applicant: Nano Nuclear Energy Inc., New York, NY (US)

(72) Inventor: Carlos Omar Maidana, Pocatello, ID (US)

(21) Appl. No.: 19/030,148

(22) Filed: Jan. 17, 2025

Related U.S. Application Data
(60) Provisional application No. 63/673,732, filed on Jul. 21, 2024.

(51) Int. Cl. G06F 30/28

(52) U.S. Cl. CPC G06F 30/28

(57) ABSTRACT

An integrated platform, method, and non-transitory computer-readable medium for optimizing performance of an electromagnetic pump is provided. In some aspects, the method includes receiving, by a design module of an integrated platform operated using a computing system, electromagnetic pump parameters corresponding to an electromagnetic pump for moving conducting fluid, and simulating, using a performance module of the integrated platform, a performance of the electromagnetic pump based on electromagnetic pump parameters received on the design module. The method also includes modifying the electromagnetic pump parameters to optimize the electromagnetic pump, and generating and transmitting, using the integrated platform, instructions for producing at least one component of the electromagnetic pump based on modified electromagnetic pump parameters.

### CROSS-REFERENCE TO RELATED APPLICATIONS

The present application is based on and claims the benefit of U.S. Provisional Application No. 63/673,732, filed on Jul. 21, 2024 and titled “Software for the Design and Analysis of Annular Linear Induction Pumps,” which is incorporated herein by reference in its entirety.

### STATEMENT REGARDING FEDERALLY SPONSORED RESEARCH AND DEVELOPMENT

This invention was made with government support under SBIR Grant Nos. DE-SC0019835, DE-SC0022805, and DE-SC0013992 awarded by U.S. Department of Energy. The government has certain rights in the invention.

### TECHNICAL FIELD

This disclosure relates generally to fluid control technologies, and more particularly, to an integrated platform and method for optimizing electromagnetic pump design and performance.

### BACKGROUND

A Molten Salt Reactor (MSR) is a type of nuclear reactor that produces heat, which can be used in electricity generation, high-temperature process heat, and other applications. Unlike traditional nuclear reactor technologies, an MSR utilizes a molten salt mixture as both coolant and fuel, with most of its volume residing in the reactor core. Molten salt can provide efficient heat removal from a reactor's core, reducing piping requirements, and decreasing overall core dimensions due to reduced component size. While operating at high temperatures and low pressures, an MSR can be efficient at generating energy, and can enhance safety by reducing risk of large breaks and loss of coolant. In addition, an MSR can generate less waste because it does not require solid fuel and infrastructure for disposing spent fuel. Furthermore, an MSR can adapt to a variety of nuclear fuel cycles (such as Uranium-Plutonium and Thorium-Uranium cycles), which can extend fuel resources. For instance, an MSR can be designed as nuclear waste “burners” or breeders.

A liquid metal-cooled reactor, such as a fast neutron reactor, is another type of nuclear reactor that is both moderated and cooled by a liquid metal solution. With a compact footprint, a liquid metal-cooled reactor can be used for electric power generation in isolated places, for fission surface power units for planetary exploration, for naval propulsion, and as part of space nuclear propulsion systems. A liquid metal-cooled reactor may be desirable for space considerations, as well as other considerations in which transportability, weight, reliability, efficiency, working environment, and so forth, are a factor.

While water could be theoretically used for reactor cooling, in practice, water has a low boiling point, and tends to slow down and absorb neutrons. This limits the amount of water that can flow through a reactor core, and any water-based cooling system would need to be operated at high pressure to provide effective cooling. Therefore, liquid metal or molten metal is typically utilized for heat removal and transport.

While molten salt and liquid-metal can provide some benefits to reactor cooling, they present technical challenges. For instance, traditional pumps for circulating liquid metal include mechanical radial or axial pump designs. However, liquid metal can be very corrosive to these traditional pumps, and cause significant damage to pump impeller, bearings, seals, and so forth. Also, traditional pumps can suffer from significant cavitation, which can cause unwanted damage, vibration, energy consumption, and reduced lifespan. Similarly, molten salt can also be highly corrosive, and corrosivity increases with temperature.

Therefore, there is a need for improved cooling and fluid control technologies.

### SUMMARY

According to some implementations of the present disclosure, a method for optimizing an electromagnetic pump for moving conducting fluid is provided. In some aspects, the method includes receiving, by a design module of an integrated platform operated using a computing system, electromagnetic pump parameters corresponding to an electromagnetic pump for moving conducting fluid, and simulating, using a performance module of the integrated platform, a performance of the electromagnetic pump based on electromagnetic pump parameters received on the design module. The method also includes modifying the electromagnetic pump parameters to optimize the electromagnetic pump, and generating and transmitting, using the integrated platform, instructions for producing at least one component of the electromagnetic pump based on modified electromagnetic pump parameters.

In other implementations of the present disclosure, a non-transitory computer-readable medium for optimizing an electromagnetic pump for moving conducting fluid is provided. In some aspects, the computer-readable medium includes instructions stored thereon, the instructions, when executed by one or more processors, cause the one or more processors to perform operations for receiving, by a design module of an integrated platform operated using a computing device, electromagnetic pump parameters corresponding to an electromagnetic pump for moving conducting fluid, and simulating, using a performance module of the integrated platform, a performance of the electromagnetic pump based on electromagnetic pump parameters received on the design module. The instructions, when executed by one or more processors, also cause the one or more processors to perform operations for modifying the electromagnetic pump parameters to optimize the performance of the electromagnetic pump, and generating and transmitting, using the integrated platform, instructions for producing at least one component of the electromagnetic pump based on modified electromagnetic pump parameters.

In yet other implementations of the present disclosure, an integrated platform for optimizing an electromagnetic pump for moving conducting fluid is provided. In some aspects, the integrated platform operated using a computing system includes a design module configured to generate a rendering of an electromagnetic pump, a performance module, in communication with the design module, configured to simulate a performance of the electromagnetic pump, and a dynamic data link configured to selectively transfer one or more electromagnetic pump parameter from the design module to the performance module, the performance module simulating the performance of the electromagnetic pump using the one or more electromagnetic pump parameter transferred. The integrated platform also includes a processor configured to execute steps to modify, based on the performance, at least one electromagnetic pump parameter to optimize the electromagnetic pump, and generate instructions for producing at least one component of the electromagnetic pump based on the at least one electromagnetic pump parameter modified.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out aspects of the present disclosure, when taken in connection with the accompanying drawings and the appended claims.

### BRIEF DESCRIPTION OF THE DRAWINGS

The foregoing and other advantages of the present disclosure will become apparent upon reading the following detailed description and upon reference to the drawings.

FIG. 1A is perspective illustration of an electromagnetic pump, according to aspects of the present disclosure;

FIG. 1B is another perspective illustration of the electromagnetic pump in FIG. 1A, according to aspects of the present disclosure;

FIG. 1C is a front view of the electromagnetic pump in FIG. 1A, according to aspects of the present disclosure;

FIG. 1D is a cross-sectional view of the electromagnetic pump in FIG. 1A, according to aspects of the present disclosure;

FIG. 2A is a perspective illustration of an example hollow duct for the electromagnetic pump in FIG. 1A, according to aspects of the present disclosure;

FIG. 2B is another perspective illustration of the hollow duct in FIG. 2A having a plurality of coil units installed thereon, according to aspects of the present disclosure;

FIG. 3A is a perspective illustration of an example core for the electromagnetic pump in FIG. 1A, according to aspects of the present disclosure;

FIG. 3B is a cross-section of the core in FIG. 3A, according to aspects of the present disclosure;

FIG. 3C is a cross-section of a portion of the core in FIG. 3A, according to aspects of the present disclosure;

FIG. 3D is another cross-section of the core in FIG. 3A, according to aspects of the present disclosure;

FIG. 3E is a side view of the core in FIG. 3A, according to aspects of the present disclosure;

FIG. 3F is another side view of the core in FIG. 3A, according to aspects of the present disclosure;

FIG. 4A is an illustration of an example coil assembly for the electromagnetic pump in FIG. 1A, according to aspects of the present disclosure;

FIG. 4B is a perspective view of a coil unit in coil assembly of FIG. 4A, according to aspects of the present disclosure;

FIG. 4C is a perspective view of the coil unit in FIG. 4C, according to aspects of the present disclosure;

FIG. 4D is an illustration of another example coil unit with a conductive matrix, according to aspects of the present disclosure;

FIG. 4E is a side view of another embodiment of a coil assembly, according to aspects of the present disclosure;

FIG. 5A is a perspective view of an example stator unit for the electromagnetic pump in FIG. 1A, according to aspects of the present disclosure;

FIG. 5B is a front view of the stator unit of FIG. 5A, according to aspects of the present disclosure;

FIG. 5C is a side view of the stator unit in FIG. 5A, according to aspects of the present disclosure;

FIG. 5D is a front view of another example stator unit, according to aspects of the present disclosure;

FIG. 6A is a perspective view of an example cooling stack for the electromagnetic pump in FIG. 1A, according to aspects of the present disclosure;

FIG. 6B is an illustration of a cooling unit in the cooling stack of FIG. 6A, according to aspects of the present disclosure;

FIG. 6C is a cross-section of the cooling unit in FIG. 6B, according to aspects of the present disclosure;

FIG. 6D is another cross-section of the cooling unit in FIG. 6B, according to aspects of the present disclosure;

FIG. 7A is a perspective view of an example cooling sleeve for the electromagnetic pump in FIG. 1A, according to aspects of the present disclosure;

FIG. 7B is another perspective view of the cooling sleeve of FIG. 7B, according to aspects of the present disclosure;

FIG. 8A is an illustration of components of a support structure for the electromagnetic pump of FIG. 1A, according to aspects of the present disclosure;

FIG. 8B is another illustration of components of a support structure for the electromagnetic pump of FIG. 1A, according to aspects of the present disclosure;

FIG. 9 is a schematic diagram of an example electromagnetic pump system, according to aspects of the present disclosure;

FIG. 10A is an illustration of an electromagnetic pump and power source, according to aspects of the present disclosure;

FIG. 10B is an electrical diagram for wiring of the electromagnetic pump of FIG. 10A, according to aspects of the present disclosure;

FIG. 10C is another electrical diagram for wiring an electromagnetic pump, according to aspect of the present disclosure;

FIG. 11 is a schematic diagram of an example integrated platform, according to aspects of the present disclosure;

FIG. 12 is a flowchart setting forth steps of a process, according to aspects of the present disclosure;

FIG. 13 is an illustration showing an example graphical user interface, according to aspects of the present disclosure;

FIG. 14A is a graph showing magnetic field as a function of a coordinate for an example electromagnetic pump, according to aspects of the present disclosure;

FIG. 14B shows a graph from simulation of current as a function of phase for various coil units on an example electromagnetic pump, according to aspects of the present disclosure;

FIG. 15A is a graph showing Lorentz force as a function of a coordinate of an example electromagnetic pump, according to aspects of the present disclosure;

FIG. 15B is a graph showing power as a function of phase for an example electromagnetic pump, according to aspects of the present disclosure;

FIG. 16 is an illustration showing temperature distribution for a stator unit and coil unit on an example electromagnetic pump, according to aspects of the present disclosure;

FIG. 17 is an illustration shown stress distribution for a hollow duct on an example electromagnetic pump, according to aspects of the present disclosure;

FIG. 18 is another illustration showing temperature distribution for a hollow duct and stator unit on an example electromagnetic pump, according to aspects of the present disclosure;

FIG. 19A is yet another illustration showing temperature distribution of cooling unit on an example electromagnetic pump, according to aspects of the present disclosure;

FIG. 19B is yet another illustration showing temperature distribution of another cooling unit on an example electromagnetic pump, according to aspects of the present disclosure.

While the present disclosure is susceptible to various modifications and alternative forms, specific implementations have been shown by way of example in the drawings and will be described in further detail herein. It may be understood, however, that the present disclosure is not intended to be limited to the particular forms disclosed. Rather, the present disclosure is to cover all modifications, equivalents, and alternatives falling within the spirit and scope of the present disclosure as defined by the appended claims.

### DETAILED DESCRIPTION

Molten salt and liquid-metal commonly used for reactor cooling can present various technical challenges to conventional pump technologies, including undesirable damage, cavitation, vibration, higher energy consumption, reduced lifespan, and so forth. Also, intense radiation, high operational temperatures, and corrosion associated with molten salt and liquid-metal present difficult conditions for conventional pump technologies.

As appreciated from description herein, the present disclosure introduces an approach that provides a number of advantages over conventional technologies, including predictability, reliability, economies of scale, and so forth. For instance, unlike conventional mechanical pumps, an electromagnetic pump, according to embodiments described herein, can operate without moving parts and seals, with little to no vibration and noise. Also, an electromagnetic pump, according to embodiments described herein, can be operated, maintained, or serviced with minimal effort or resources. Furthermore, the present disclosure provides an integrated platform for design and analysis of an electromagnetic pump, in accordance with embodiments described, allowing for modeling and simulation of performance, and integrating both computer-aided design and computer-aided engineering capabilities.

The present disclosure is described with reference to the attached figures, where like reference numerals are used throughout the figures to designate similar or equivalent elements. The figures are not drawn to scale, and are provided merely to illustrate the instant disclosure. Several aspects of the disclosure are described below with reference to example applications for illustration. It may be understood that numerous specific details, relationships, and methods are set forth to provide a full understanding of the disclosure. One having ordinary skill in the relevant art, however, will readily recognize that the disclosure can be practiced without one or more of the specific details, or with other methods. In some instances, some structures or operations may not be shown in detail to avoid obscuring the disclosure. The present disclosure is not limited by illustrated ordering of steps, acts or events, as some steps, acts, or events may occur in different orders and/or concurrently with other steps, acts, or events. Furthermore, not all illustrated steps, acts, or events are required to implement an approach described in the present disclosure.

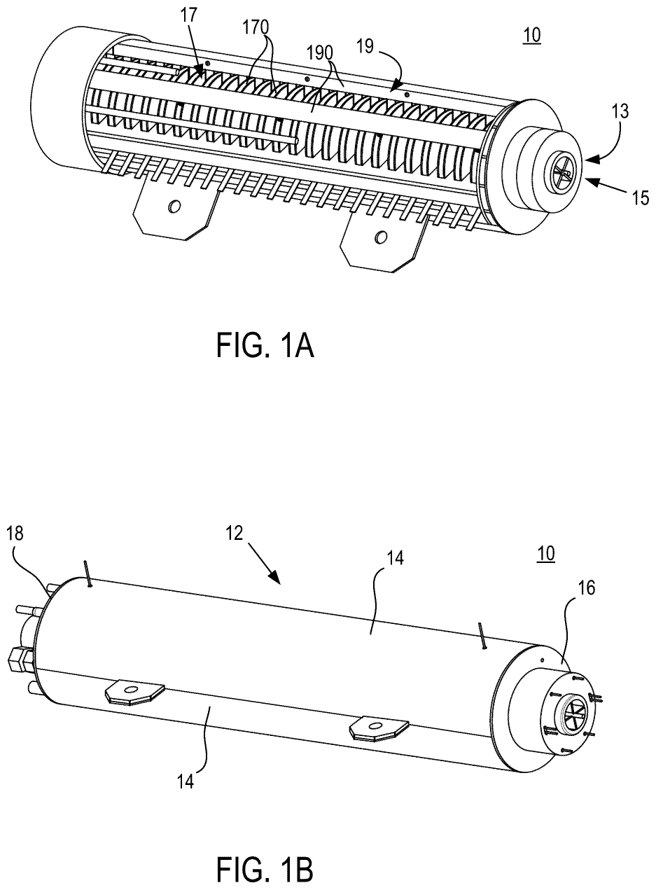

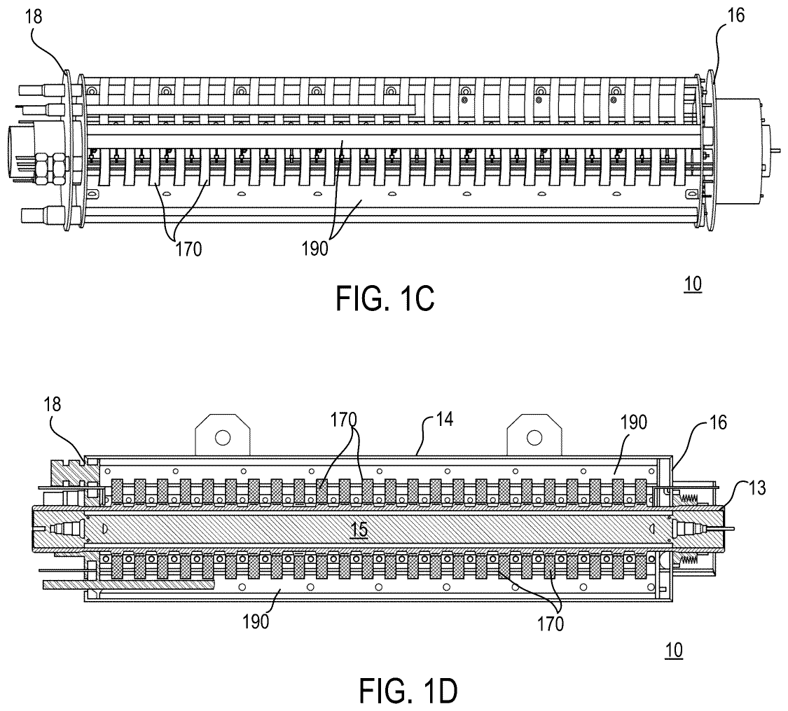

Turning now to FIGS. 1A to 1D, an electromagnetic pump 10 for moving a conductive fluid, in accordance with aspects of the present disclosure, is illustrated. In some non-limiting applications, the electromagnetic pump 10 may be used to control a temperature of a reactor, or reactor core.

Referring specifically to FIG. 1A, the electromagnetic pump 10 may generally include a hollow duct 13, a core 15, a coil assembly 17 that includes a number of coil units 170, and a stator assembly 19 that includes a number of stator units 190. In some embodiments, as shown in FIG. 1B, the electromagnetic pump 10 may include a support system 12 to secure and protect various components of the electromagnetic pump. For instance, in some embodiments, the support system 12 may include an enclosure formed by one or more shell 14, a first end plate 16, a second end plate 18, which when assembled, at least partially encase the hollow duct 13, the core 15, the coil assembly 17, and the stator assembly 19, as illustrated in FIG. 1B.

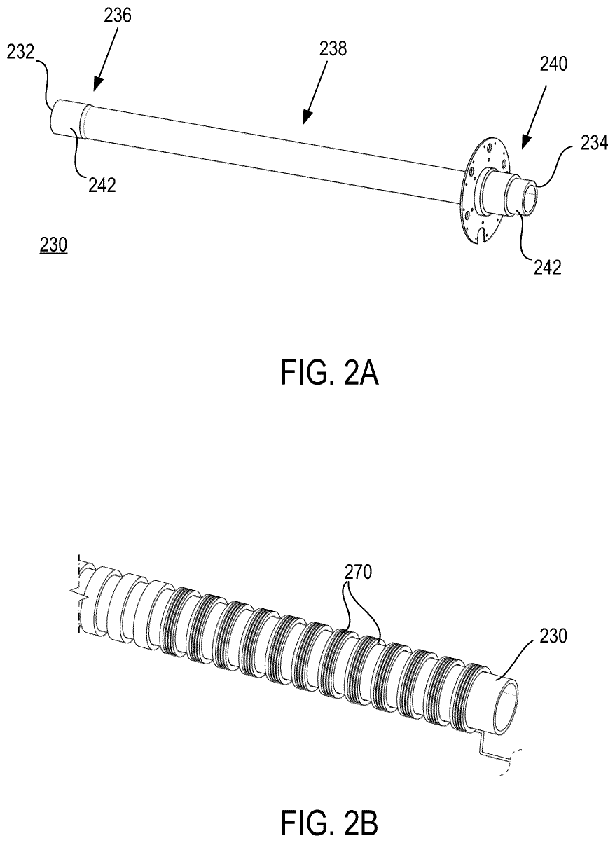

Referring particularly to FIGS. 2A and 2B, one embodiment of a hollow duct 230, in accordance with aspects of the present disclosure, is illustrated. As shown, the hollow duct 230 extends from a first duct end 232 to a second duct end 234, and may include an inlet portion 236, a central portion 238, and an outlet portion 240. In some embodiments, the inlet portion 236, the outlet portion 240, or both, may include an enlarged section 242 with an outer diameter that is larger than the outer diameter of the hollow duct 230 at the central portion 238. The enlarged section 242 may help facilitate installation and/or securing of one or more component thereto, such as a structure plate, as illustrated in FIG. 2A. In some embodiments, the hollow duct 230 may have a number of coil units 270 arranged thereon, as illustrated in FIG. 2B

A shape, dimension, and/or material used to form the hollow duct 230 may vary. In some applications, material used to form the hollow duct 230 may be compatible with high temperature operation and/or corrosive environment. For example, the hollow duct 230 may be produced using a high-temperature alloy material, such as a Ni—Cr alloy material (e.g., Hastelloy, Iconel 617, and so forth). In some embodiments, the hollow duct 230 may include one or more protective layers that line(s) an inner and/or outer surface the hollow duct 230. Such protective layer(s) may have a thickness of at least 50 micrometers, or more. By way of example, a protective layer may include as a Ni layer, an alumina layer, and so forth.

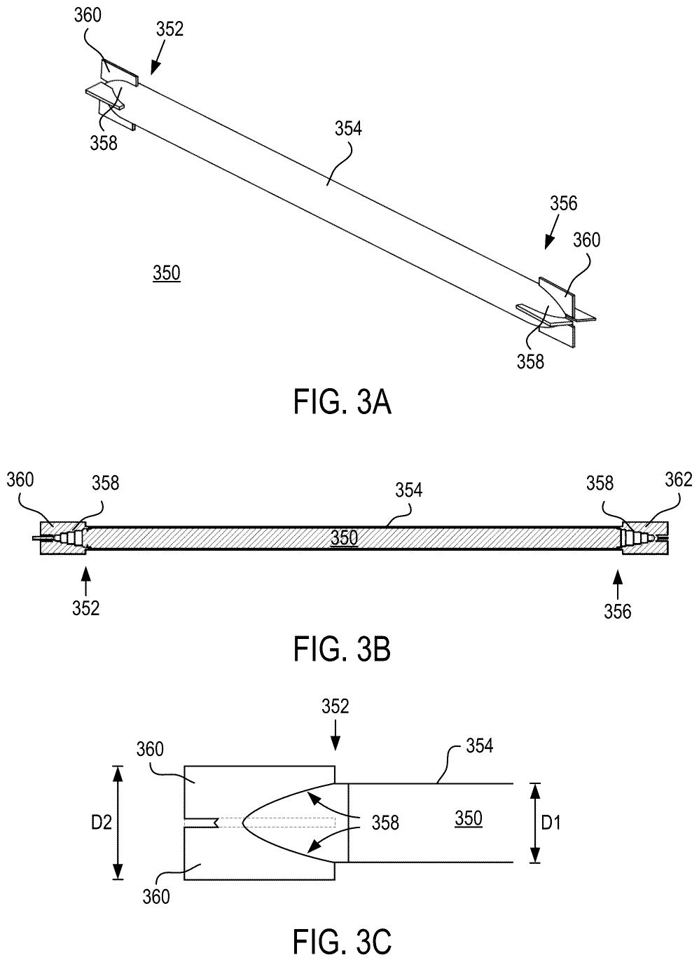

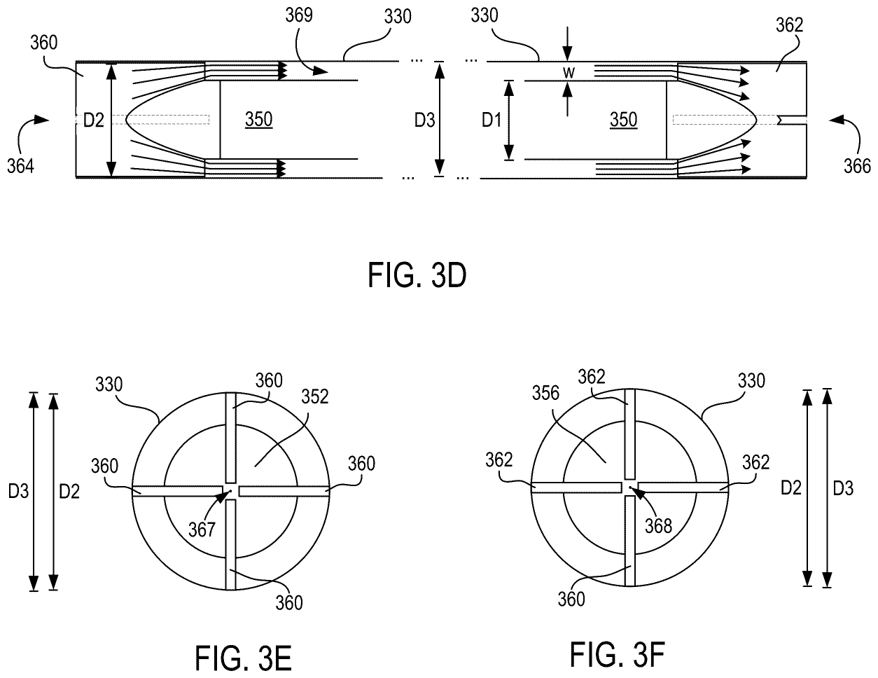

Referring particularly to FIGS. 3A-3F, one embodiment of a core 350, in accordance with aspects of the present disclosure, is illustrated. Referring particular to FIGS. 3A and 3B, the core 350 may include a first core end 352, a core body 354, and a second core end 356. The first core end 352, the second core end 356, or both may be integrated with or connected to the core body 354 in any number of ways, such as using fasteners, interference fitting. forming, welding, threading, and so forth. In some embodiments, an outer diameter D1 of the first core end 352 and the second core end 356 of the core 350 may include a taper 358, as illustrated in FIG. 3C. In some embodiments, the taper 358 may be configured to prevent or minimize turbulent flow movement of conducting fluid. As illustrated in FIG. 3A, the core 350 may be in the form of a torpedo core.

In some embodiments, the core 350 may include a first set of fins 360 at the first core end 352 and a second set of fins 362 at the second core end 356. The first set of fins 360, may be attached to, or may extend from, the first core end 352, and the second set of fins 362, may be attached to, or may extend from, the second core end 356. As shown in FIG. 3D, the first set of fins 360, and the second set of fins 362, may extend radially outward to an outer diameter D2. While FIGS. 3A to 3F show each set of fins to include 4 fins, fewer or more fins may be possible.

In some embodiments, an interior of the core 350 includes a solid rod. In other embodiments, the interior of the core 350 includes a tube. In yet other embodiments, the interior of the core 350 includes a radially laminated rod or a radially laminated tube. The interior of the core 350 may include a magnetic material, although other materials. For instance, in some embodiments, the interior of the core 350 may include a magnetic rod or magnetic tube made from magnetic material. In one non-limiting example, the magnetic material may include a Fe—Co—V alloy material. In particular, utilizing a magnetic material in the interior of the core 350 may help direct or control a component of magnetic field (e.g., a radial component) generated by a coil assembly, as described herein. For instance, by way of structure and/or magnetization of magnetic material in the interior of the core 350, magnetic field generated by one or more coil units of the coil assembly by may be directed radially at one or more point on the outer diameter of the core 350, and help close a magnetic circuit for the magnetic field.

In some implementations, the core 350 may be positioned inside a hollow duct 330, as illustrated in FIGS. 3D to 3F. When positioned inside the hollow duct 330, the first set of fins 360 and the second set of fins 362 of the core 350 may be used align the core 350 inside the hollow duct 330. To this end, each fin of the first set of fins 360 and the second set of fins 362 may extend radially to an outer diameter D2 that is close to an inner diameter D3 of the hollow duct 330, as shown in FIG. 3D. For instance, in some embodiments, a difference between the outer diameter D2 and the inner diameter D3 of the hollow duct 330 may provide sufficient clearance for inserting the core 350 inside the hollow duct 330, as well as maintaining a tight or interference fit between the hollow duct 330 and the core 350. For example, a difference between the outer diameter D2 and inner diameter D3 may be approximately 0.01″, or less, may provide such sufficient clearance.

When assembled, the hollow duct 330 and core 350 form a conducting fluid pathway that may carry a conducting fluid therethrough. For instance, in some applications, the conducting fluid may include a fluid at a high temperature, such as a molten salt, a liquid metal, and so forth. The conducting fluid pathway produced by the hollow duct 330 and core 350 may extend from an inlet 364 at the first core end 352 of the core 350 to an outlet 366 at the second core end 356 of the core 350, as illustrated in FIG. 3D. In some embodiments, the inlet 364 may include an inlet nozzle 367 produced by the first set of fins 360, as seen in FIG. 3E. Similarly, the outlet 366 may include an outlet nozzle 368 produced by the second set of fins 362, as seen in FIG. 3F. As appreciated from FIGS. 3E and 3F, the inlet 364 may include other openings produced by the first set of fins 360, and the outlet 366 may include other openings produced by the second set of fins 362. In some embodiments, at least a portion of the conducting fluid pathway includes an annular channel 369 with a width w defined by a difference between the outer diameter DI of the core 350 and the inner diameter D3 of the hollow duct 330, as shown in FIG. 3D.

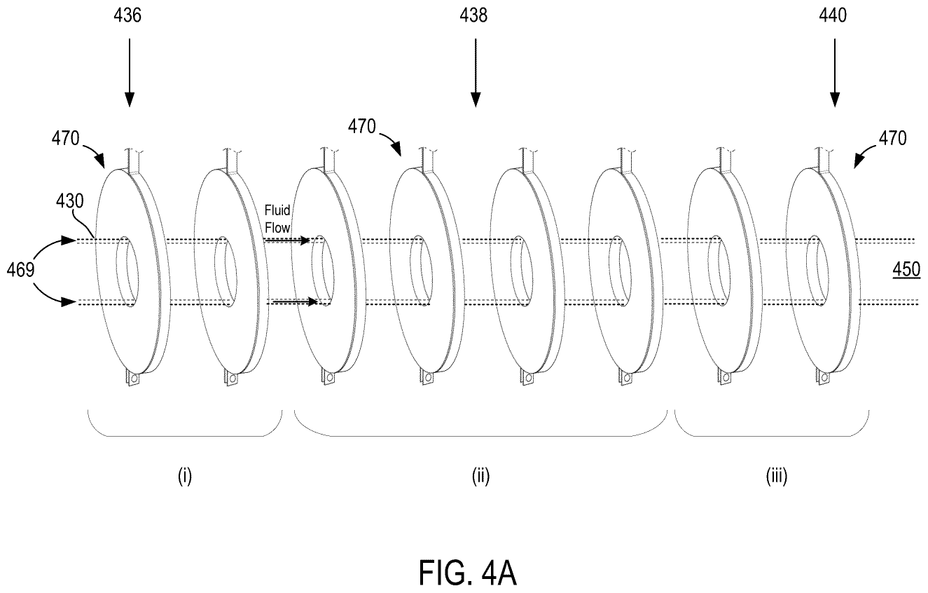

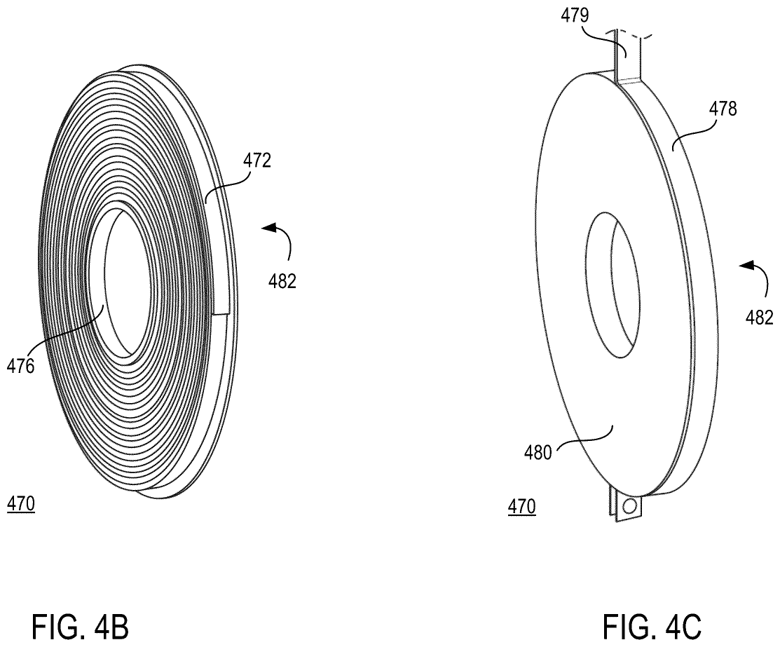

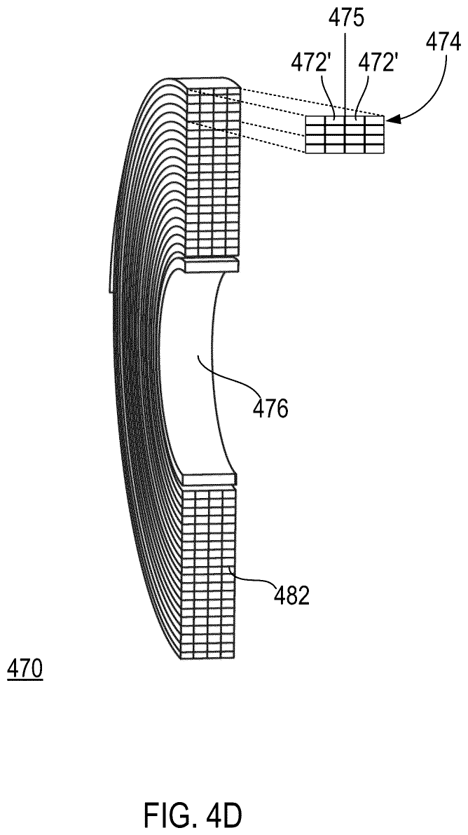

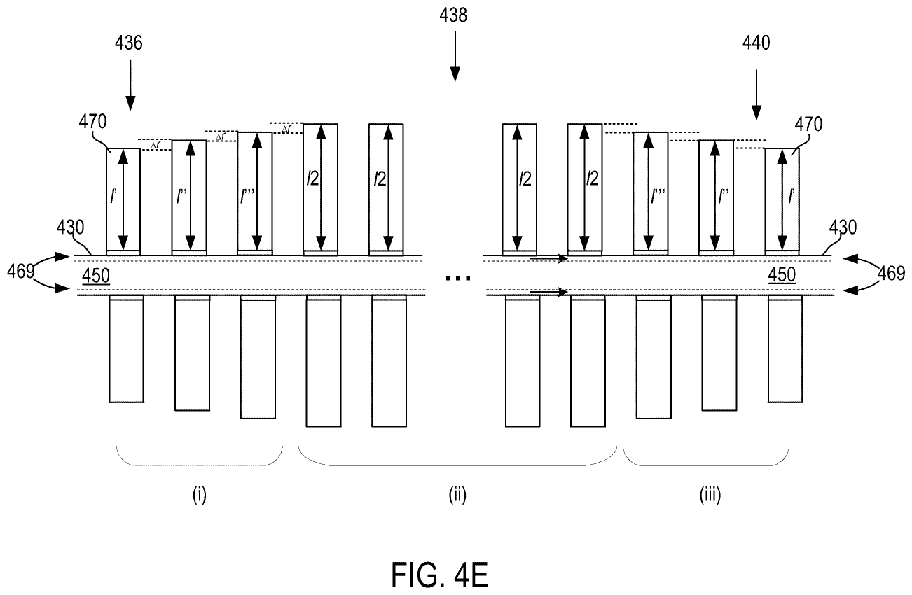

Turning now to FIGS. 4A to 4D, an example of a coil assembly 17, in accordance with aspects of the present disclosure, is illustrated. As shown, in some embodiments, the coil assembly 17 may include a number of coil units 470, where a coil unit 470 may be arranged about a hollow duct 430 and core 450, as described with reference to FIGS. 2A-2B, and 3A-3F.

In some embodiments, a coil unit 470 of the coil assembly 17 may include a winding of a conductive strip 472 (FIG. 4B). The winding of the conductive strip 472 may have any number of turns, such as 80 turns, or less, or more. To prevent electrical shorting upon winding, the conductive strip 472 may include one or more layer of insulating material (e.g., alumina). In some embodiments, a coil unit 470 may include a conductive matrix 474 that includes a number of conductive strips 472′ arranged in the array (FIG. 4D). Conductive strips 472′ in the conductive matrix 474 that are adjacent to one another may be separated by an insulating barrier 475 to prevent electrical shorting, as illustrated in FIG. 4D. In addition, the conductive matrix 474 may also include one or more layer of insulating material coating the conductive matrix 474 to prevent electrical shorting upon winding of the conductive matrix 474.

The conductive strip 472 or conductive matrix 474 may be wound about a stator ring 476, as illustrated in FIGS. 4B and 4D. In some embodiments, the stator ring 476 may have an inner diameter that corresponds to an outer diameter of the hollow duct 430, as shown in FIG. 4A. The stator ring 476 may be made using any material, such as calcium silicate material. In some applications, the stator ring 476 may help control overheating/stress damage to the coil unit 470.

In some embodiments, a circular clamp 478 may be attached or attachable to an outer diameter of a coil unit 470, where the circular clamp 478 is configured to make an electrical connection to the conductive strip 472, conductive matrix 474, or portion thereof, on the outer diameter of the coil unit 470, as shown in FIG. 4C. In some embodiments, the circular clamp 478 may include a strap 479 that extends radially outward from the circular clamp 478. The circular clamp 478 may be attached and tightened around the outer diameter of the coil unit 470, for example, using a fastener. In some embodiments, a portion of the circular clamp 478 and/or strap 479 may be configured to allow electrical contact thereto. For instance, the circular clamp 478 and/or strap 479 may include a conducting material (e.g., copper).

In some embodiments, the coil unit 470 may also include a first disk 480 on a first side of the coil unit 470 and a second disk 482 and the second side of the coil unit 470. The first disk 480 may be attached or attachable to the first side of the coil unit 470. Similarly, the second disk 482 may be attached or attachable to the second side of the coil unit 470. For example, the first disk 480 and the second disk 482 may be attached to the stator ring 476 via tight or interference fit, or other method of attachment. The first disk 480, the second disk 482, or both, may be configured provide support, protection, and/or electrical isolation for the conductive strip 472 or the conductive matrix 474 wound therebetween. For instance, the first disk 480, and the second disk 482 may include an insulating material. In some embodiments, the first disk 480 and/or second disk 482 may include an access (e.g., an opening therein), allowing for electrical connection to the conductive strip 472, conductive matrix 474, or portion hereof, on the inner diameter of the coil unit 470.

The coil units 470 of the coil assembly 17 may be selectively operable and/or configured to generate and control magnetic field generated in or about an annular channel 469 produced by the hollow duct 430 and core 450, as shown in FIG. 4A. For instance, in embodiments, the coil assembly 17 may include a first set (i) of coil units 470, a second set (ii) of coil units 470, and a third set (iii) of coil units 470, as illustrated in FIG. 4A. As shown, the first set (i) of coil units 470 may be arranged near or about an inlet portion 436 of the hollow duct 430. The second set (ii) of coil units 470 may be arranged near or about a central portion 438 of the hollow duct 430, and the third set (iii) of coil units 470 may be arranged near or about the outlet portion 440 of the hollow duct 430.

Configuration and/or operation of the first set (i), second set (ii), and/or third set (iii) of coil units 470 may vary. For instance, a winding of conductive strip 472 or conductive matrix 474 in respective set of coil units 470 may vary. For example, in some embodiments, a winding of conductive strip 472 or conductive matrix 474 in the first set (i) of coil units 470 and in the third set (iii) of coil units 470 may be less (i.e., fewer turns) than the winding of conductive strips 472 or conductive matrix 474 in the second set (ii) of coil units 470, as illustrated in FIG. 4E. Further, in some embodiments, a winding of conductive strip 472 or conductive matrix 474 in the first set (i) of coil units 470 and in the third set (iii) of coil units 470 may decrease by a predetermined value (i.e., corresponding to a change in radius, Δr, of the respective coil unit 470 in FIG. 4E) in a direction away from the central portion 438 of the hollow duct 430. Such variation in winding may be used to generate magnetic field gradients that may help control a profile of magnetic field (e.g., longitudinal magnetic field values, radial magnetic field values, lateral magnetic field values, and so forth) in the annular channel 469, and particularly magnetic field near the inlet portion 436 and the outlet portion 440 of the hollow duct 430.

Coil units 470 of the coil assembly 17 may be individually and/or collectively connected or connectable to one or more power source (e.g., a voltage source, a current source, and so forth) that may supply power for energizing the coil units 470 and generating a time-varying magnetic field in the annular channel 469. In some embodiments, the one or more power source may be configured to provide power signals in various phases to the coil units 470. For instance, in some implementations, coil units 470 in the first set (i) of coil units 470, the second set (ii) of coil units 470, and the third set (iii) of coil units 470 may be connected or connectable, using a wiring assembly, and operated in a three-phase winding arrangement. For instance, the coil units 470 may be connected and operated using an AA ZZ BB XX CC YY sequence, where A, B, C represent a balanced three-phase winding arrangement, and X, Y, Z, represent an opposite phase. For example, for phases A:0°, B:120° and C:240°, phases may be X:180°, Y:300° and Z:60°.

While FIG. 4A illustrates one example of a coil assembly 17, various modifications may be possible. For instance, the coil assembly 17 may include more or fewer coil units 470. More particularly, fewer or more coil units 470 may be included in the first set (i) of coil units 470, the second set (ii) of coil units 470, and the third set (iii) of coil units 470, or in a combination thereof.

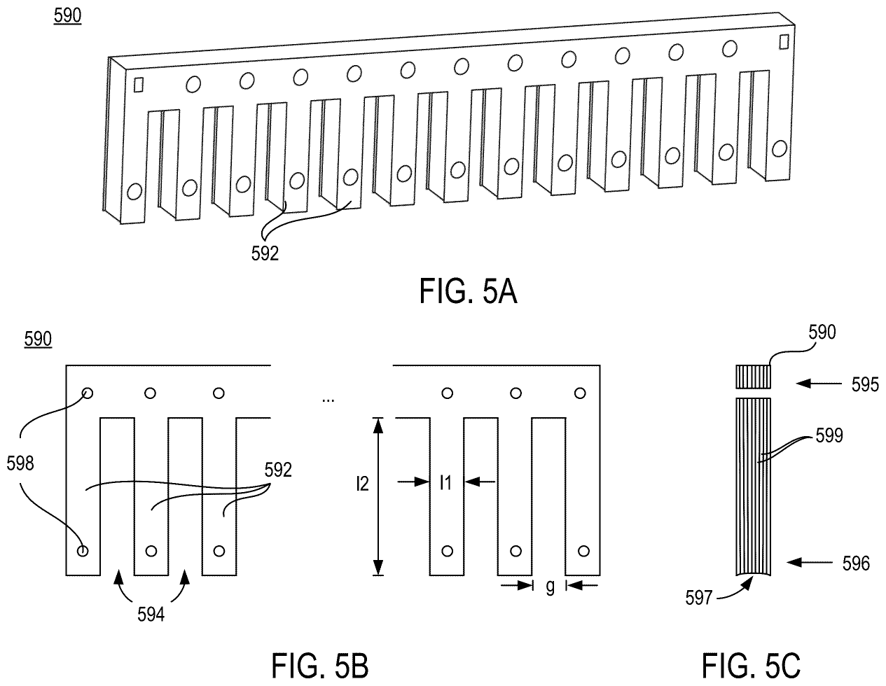

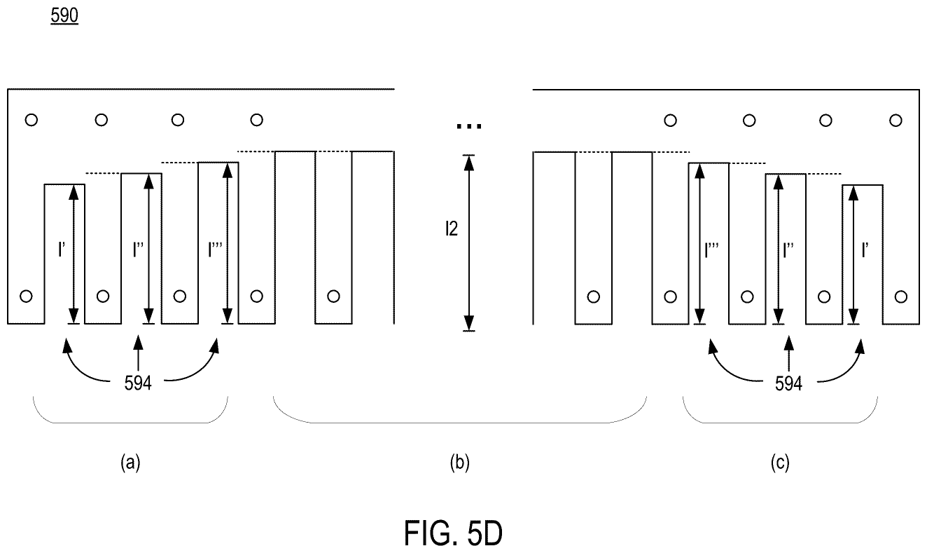

As described, the electromagnetic pump 10 includes a stator assembly 19 with a number of stator units 190. As illustrated in FIGS. 5A and 5B, in some embodiments, a stator unit 590 may include a number of dividers 592 of with longitudinal dimension 11 and lateral dimension 12. The dividers 592 may be separated by gaps 594 with longitudinal dimension g. Each gap 594 of the stator unit 590 may be configured to receive a section of a coil unit in a coil assembly, for instance, as described with reference to FIGS. 4A-4D. In particular, a coil unit 470 may be positioned in a gap 594 between the dividers 592, for instance, in a tight or interference fit (e.g., leaving a space of approximately 0.01″, or less).

As illustrated in FIG. 5C, a divider 592 of the stator unit 590 extends from an upper portion 595 to a lower portion 596, where the lower portion 596 may include a curved portion 597, which allows the stator unit 590 to be positioned on an outer diameter of a hollow duct, for instance, as described with reference to FIGS. 2A-2B. In some embodiments, a curvature of the curved portion 597 substantially matches the curvature of the outer diameter of the hollow duct. In some embodiments, a stator assembly may include 4 stator units 590, positioned every 90 degrees around a circumference of a hollow duct, as described. In yet other embodiments, a stator assembly may include 6 stator units 590, positioned every 60 degrees around the circumference of the hollow duct.

In some embodiments, the stator unit 590 may be attached or attachable to a support structure, for instance, as described with reference to FIGS. 1A and 1B. To this end, the stator unit 590 may include a number of openings 598 for receiving a number of fasteners, as shown in FIGS. 5A and 5B.

In some embodiments, the stator unit 590 may be configured to direct a time-varying magnetic field, generated by one or more coil units 470, in a direction perpendicular to the direction of flow of the conducting fluid, as shown in FIG. 3D, for example. To this end, a structure and/or material of the stator unit 590 may be configured to control a direction of a time-varying magnetic field. For example, in some embodiments, the stator unit 590 may include a number of stator sheets 599, as illustrated in FIG. 5C. In some embodiments, stator sheets 599 in a stator unit 590 may be separated by an insulating material or may be laminated to form laminated sheets. The stator sheets 599 may extend radially as shown in FIG. 5C. In some embodiments, the stator sheets 599 may include a magnetic material. By way of example, the stator unit 590 may include a Ni—Cr—Co—Mo alloy material or a Fe—Si Steel material. The stator sheets 599 and/or magnetic material therein may direct magnetic field generated by one or more coil units of the coil assembly radially (i.e., along a length of the stator sheets 599 shown in FIG. 5C), thereby helping to close a magnetic circuit for the magnetic field via a core, as described.

As illustrated in FIG. 5B, in some embodiments, gaps 594 of a stator unit 590 may be defined by a lateral dimension l2 and longitudinal dimension g. However, dimensions of the gaps 594 may vary in a stator unit 590. For instance, a stator unit 590 may include gaps 594 with more than one lateral dimension. In one example, a stator unit 590 may include a first set (a) of gaps 594, a second set (b) of gaps 594, and a third set (c) of gaps 594, as illustrated in FIG. 5D. In particular, gaps 594 in the first set (a) and the third set (c) of gaps 594 may defined by a number of lateral dimensions l′, l″, l′″, and so forth, which are less than the lateral dimension l2 of gaps 594 in the second set (b) of gaps 594, as shown. As illustrated, lateral dimensions l′, l″, l′″ may decrease longitudinally, in a direction away from a center of the stator unit 590.

As described, a coil assembly may include coil units with multiple windings. For instance, in some embodiments, a coil assembly may include a first set (i), a second set (ii), a third set (iii) of coil units, where a winding of coil units in the first set (i) of coil units and in the third set (iii) of coil units is less than the winding of coil units in the second set of coil units, and the winding of successive coil units in the first set (i) of coil units and in the third set of coil units decreasing longitudinally, in a direction away from a center of the electromagnetic pump. Hence, in some embodiments, the first set (a) of gaps 594, the second set (b) of gaps 594, and the third set (c) of gaps 594 may be configured to receive the first set (i) of coil units, the second set (ii) of coil units, and the third set (iii) of coil units, respectively.

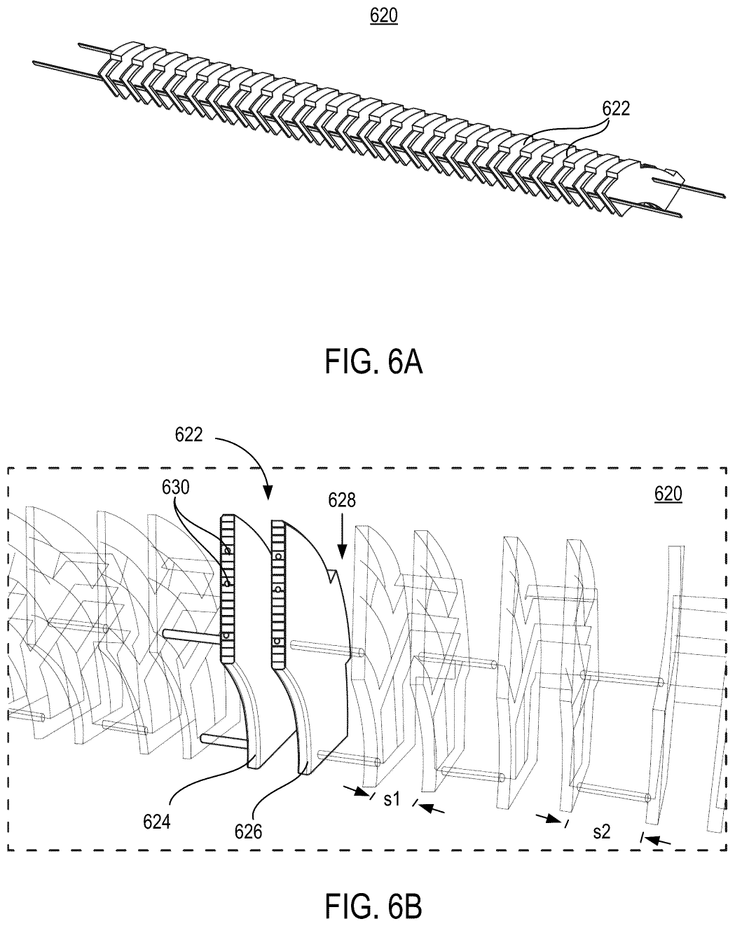

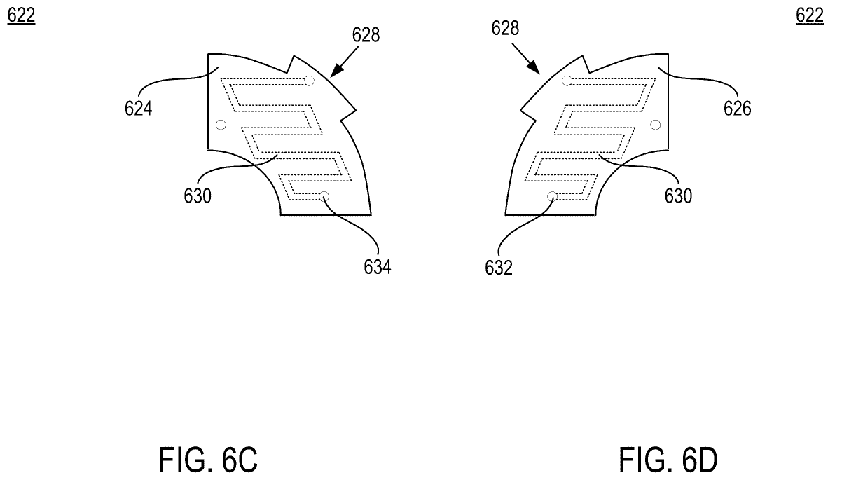

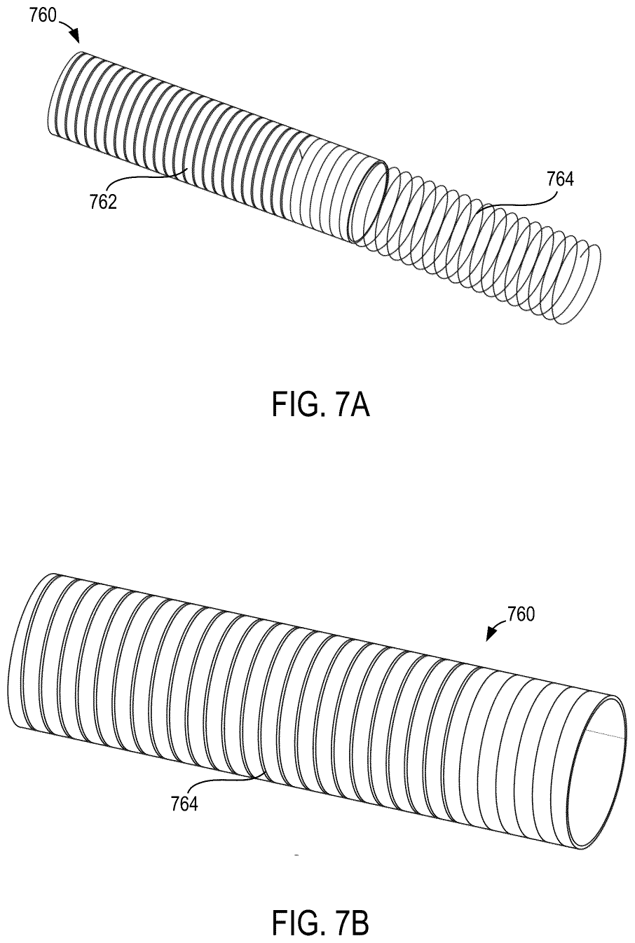

As described, an electromagnetic pump may be operated at high temperatures. To this end, a cooling system may be used to control temperature. Turning to FIGS. 6A to 6D, an example of a cooling stack 620 of a cooling system, in accordance with aspects of the present disclosure, is illustrated. The cooling stack 620 may include a number of cooling units 622 arranged longitudinally in sequence, and fluidly connected to one another, as shown in FIG. 6B. A cooling unit 622 may include a first cooling plate 624, a second cooling plate 626 spaced by a separation s1 from the first cooling plate 624, and a connector plate 628 connecting the first cooling plate 624 and the second cooling plate 626. Cooling units 622 arranged successively in the cooling stack 620 may be separated by a separation s2, as shown in FIG. 6B.

As illustrated in FIGS. 6B-6D, the first cooling plate 624, the second cooling plate 626, and connector plate 628 may include a network of microchannels 630 running therethrough, where the microchannels 630 may carry a cooling fluid entering the cooling unit 622 through at least one cooling unit input 632 and exiting the cooling unit 622 through at least one cooling unit output 634. The arrangement of the network of microchannels 630 may vary.

In some embodiments, the separation s1 between the first cooling plate 624 and the second cooling plate 626 may be configured to correspond to a width of a coil unit 470, as described with reference to FIGS. 4A-4D. In this manner, the coil unit 470 may be positioned between the first cooling plate 624 and the second cooling plate 626 to provide cooling to the coil unit 470.

In some embodiments, a cooling system, in accordance with aspects of the present disclosure, may include a cooling sleeve 760, as illustrated in FIGS. 7A and 7B. The cooling sleeve 760 may include a helical channel 762 extending along a length of the cooling sleeve 760. As shown, the helical channel 762 may receive a helical cooling coil 764 (e.g., coiled tubing) that may carry a cooling fluid to cool the cooling sleeve 760, and components arranged therein. The cooling sleeve 760 may be configured, for example, by way of an inner diameter, to fit around one or more components, such as stator units 590 as described with reference to FIGS. 5A-5C, and coil units 470, as described with reference to FIGS. 4A-4D.

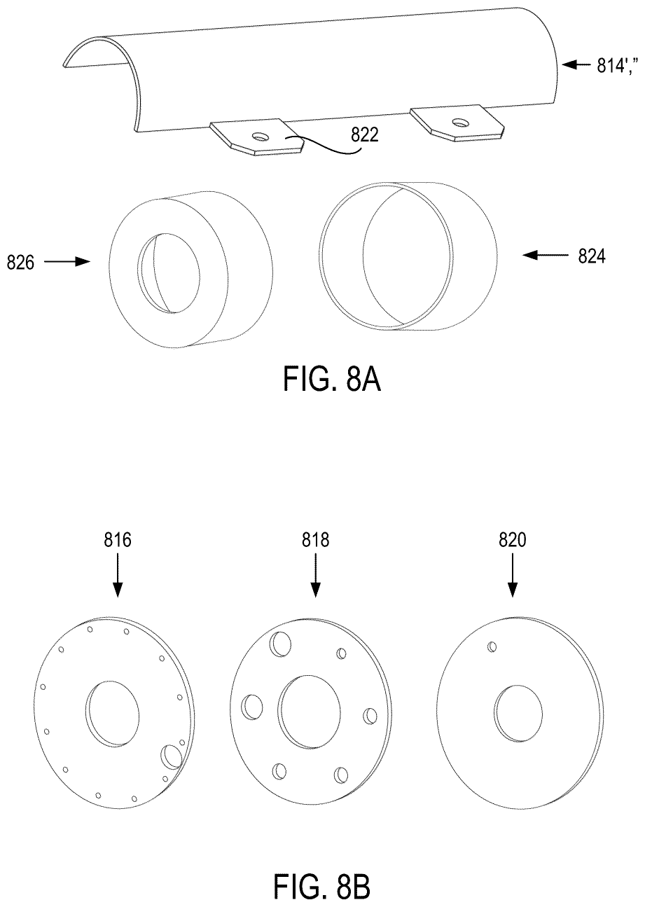

As described, an electromagnetic pump, in accordance with aspects of the present disclosure, may include a support structure with various components. The components of the support structure may be connected using various methods, such as welding, brazing, fastening, and so forth. In some embodiments, illustrated in FIGS. 8A and 8B, the support structure may include a first shell 814′ and a second shell 814″, a first end plate 816, a second end plate 818, a third plate 820. As illustrated, the first shell 814′ and the second shell 814″ may include one or more tabs 822 with openings extending therefrom, allowing for the first shell 814′ and the second shell 814″ to be fastened together, e.g., using bolts, screws, or other fasteners. Also, the first end plate 816, a second end plate 818, a third plate 820, may include various openings, for instance, to provide access for the hollow duct, as well as various sensors, instrumentation, fasteners, filler, and so forth. The support structure may also include at least one end collar 824 and at least one cover 826, shown in FIG. 8A. Together, components of the support structure can provide structural rigidity, access, and/or protection of components of the electromagnetic pump.

In some implementations, an electromagnetic pump, as described, may be assembled by attaching or connecting cooling stacks to a coil assembly, where cooling units of the cooling stacks are arranged longitudinally in sequence, and inserted between coil units, for instance, in a tight or interference fit. The cooling stacks and coil assembly may then be positioned about a hollow duct, whereby tubing from the cooling stacks is inserted through openings in a first end plate. A stator assembly may then be attached, whereby a stator unit is fixed using one or more fastener. In some implementations, thermocouple bars may be installed using openings in the first end plate. A helical cooling coil may then be installed in the helical channel of a cooling sleeve, and the cooling sleeve may then be positioned about over the stator assembly, coil assembly, and cooling stacks. A second end plate may then be positioned on the electromagnetic pump, whereby tubing of the cooling stacks is inserted through openings in the second end plate. The stator assembly may be fastened to the second end plate using various fasteners. An end collar may then be installed on the second duct end, and secured in place (e.g., via welding). The core may be inserted into the hollow duct, and an end cover may then be attached to the second plate. Shell components may then be installed over the electromagnetic pump, and secured in place (e.g., using fasteners, welding, and so forth). In some implementations, an internal space of the electromagnetic pump, such as the space defined by the shell(s), end plate(s), hollow duct, stator units, and coil units, may be filled with a filler. In some embodiments, the internal space may be filled with a material that is electrically insulating. Alternatively, or additionally, the internal space may be filled with a material that is thermally conductive. For example, the filler may include a Ceralloy powder.

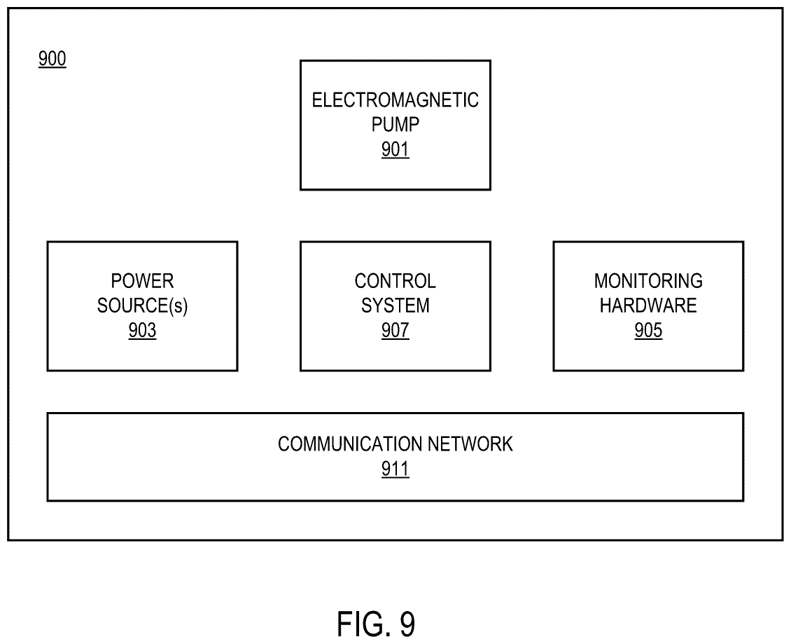

Turning to FIG. 9, an example of an electromagnetic pump system 900, according to aspects of the present disclosure, is illustrated. In some embodiments, the electromagnetic pump system 900 may include an electromagnetic pump 901, one or more power sources 903 to power the electromagnetic pump 901, and monitoring hardware 905 to monitor operation of the electromagnetic pump 901.

In particular, the electromagnetic pump 901 may be configured to move conducting fluid, in accordance with aspects of the present disclosure. For instance, in some embodiments, the electromagnetic pump 901 may include a hollow duct extending from a first duct end to a second duct end, where the hollow duct includes an inlet portion, a central portion, and an outlet portion. The electromagnetic pump 901 may also include a core positioned inside the hollow duct that extends from a first core end to a second core end, where the hollow duct and the core form an annular channel for carrying the conducting fluid.

In some embodiments, the electromagnetic pump 901 may include a coil assembly with a plurality of coil units, as described. In some embodiments, the coil assembly may include a first set of coil units arranged about the inlet portion of the hollow duct, a second set of coil units arranged about the central portion of the hollow duct, and a third set of coil units arranged about the outlet portion of the hollow duct. The coil units may be operable to generate a time-varying magnetic field that can move the conducting fluid through the annular channel of the electromagnetic pump 901.

In some embodiments, the electromagnetic pump 901 may include a stator assembly with a plurality of stator units, as described. In some embodiments, a stator unit may be configured to receive various coil units in a coil assembly. For instance, the stator unit may include a number of gaps, each receiving a section of a coil unit, such as a coil unit of the first set of coil units, the second set of coil units, and/or the third set of coil units, as described. In sone embodiments, a stator unit may be configured to direct magnetic field generated by coil units positioned in the gaps of the stator unit. In particular, the stator unit may be configured to direct magnetic field radially along a direction perpendicular to the direction of flow of the conducting fluid, as described.

In some embodiments, the electromagnetic pump 901 may include a cooling system with a number of cooling stacks, where each stack includes a number of cooling units arranged longitudinally in sequence, and fluidly connected to one another, as described. In some embodiments, a cooling unit may include a first cooling plate with at least one cooling unit input, a second cooling plate parallel to the first cooling plate that includes at least one cooling unit output. The cooling unit may also include at least one connector plate connecting the first cooling plate and the second cooling plate, and a network of microchannels formed in the first cooling plate, the second cooling plate, and the connector plate(s), where the network of microchannels connects the cooling unit input(s) on the first cooling plate to the cooling unit output(s) on the second cooling plate to form one or more fluid pathways for cooling fluid to flow therethrough.

The power source(s) 903 may include various systems, devices, components, hardware, and so forth, which may be configured to controllably supply power for energizing coil units of the coil assembly of the electromagnetic pump 901. In some embodiments, the power source(s) 903 may be configured to provide one or more time-varying power signal with one or more predefined phase. In this manner, the power source(s) 903 may controllably generate a time-varying magnetic field in or about the annular channel of the electromagnetic pump 901 to pump conducting fluid in the annular channel. By way of example, the power source(s) 903 may include one or more voltage source, one or more current source, or a combination thereof.

The monitoring hardware 905 may include various systems, devices, components, hardware, and so forth, configured to monitor operation of the electromagnetic pump 901. For instance, the monitoring hardware 905 may include various digitizers, filters, amplifiers, integrators, differentiators, data loggers/recorders, data acquisition cards, and so forth, capable of receiving, as well as conditioning, signals captured by one or more sensors positioned on or about the electromagnetic pump 901.

For example, in some embodiments, the monitoring hardware 905 may receive temperature readings from one or more temperature sensors (e.g., thermocouple sensor(s)) arranged to capture temperature signals of various components on the electromagnetic pump 901, such as the coil assembly, stator assembly, and so forth. In some embodiments, the monitoring hardware 905 may receive pressure readings from one or more pressure sensors arranged to capture pressure signals of various components on the electromagnetic pump 901. For instance, in one example, the pressure sensor(s) may receive pressure readings corresponding to conducting fluid entering and/or exiting the electromagnetic pump 901. In another example, the pressure sensor(s) may receive pressure readings corresponding to cooling fluid in the cooling system of the electromagnetic pump 901. In some embodiments, the monitoring hardware 905 may receive current readings from one or more current sensors arranged to capture current signals corresponding to current flowing in one or more coil unit of the coil assembly of the electromagnetic pump 901. In some embodiments, the monitoring hardware 905 may receive magnetic field readings from one or more magnetic field sensors (e.g., Hall probe(s)) arranged to capture magnetic field signals corresponding to time-varying magnetic field generated by one or more coil units of the coil assembly of the electromagnetic pump 901. In some embodiments, the monitoring hardware 905 may receive flow readings from one or more flow sensors (e.g., electromagnetic flow meter) arranged to capture flow signals corresponding to conducting fluid pumped by the electromagnetic pump 901.

In some embodiments, the monitoring hardware 905 may also include or communicate with various systems, devices, components, hardware, and so forth, configured to monitor operation of other systems, devices, and equipment, such as systems, devices, and equipment associated with a reactor.

Referring again to FIG. 9, in some, the electromagnetic pump system 900 may also include a control system 907, as shown. The control system 907 may include various systems, devices, components, hardware, and so forth, configured to control operation of the electromagnetic pump 901 and/or various components therein. For example, the control system 907 may include a workstation, personal computer, laptop, tablet, smartphone, microcontroller, and so forth.

In some embodiments, the control system 907 may include one or more processor configured, via programmed and/or hardwired instructions, for carrying out various steps to control operation of the electromagnetic pump 901 and/or various components therein. As such, the control system 907 may be configured to receive and/or process various data and information, as well as generate and provide various data, information, and signals. For instance, the processor(s) may be configured to generate, or direct another component on or connected to the control system 907 (e.g., a signal generator) to generate, one or more control signal, such as a voltage signal, current signal, optical signal, and so forth. In one example, one or more power control signals may be generated to select one or more characteristics of a power signal, such as amplitude, phase, frequency, and so forth. In some implementations, power control signal(s) may be generated based on a predetermined flow of a conducting fluid through a reactor, or based on a predetermined temperature of a reactor, or based on a predetermined cooling rate of a reactor, and so forth. Responsive to the power control signal(s), the power source(s) 903 may output one or more power signals with the selected characteristic(s). In another example, one or more cooling control signals may be generated to control a temperature on the electromagnetic pump 901. Responsive to the cooling control signal(s), a cooling controller (e.g., a pump) may control a flow of cooling fluid, for example, in the cooling system of the electromagnetic pump 901.

The control system 907 may include various components and/or hardware for receiving and/or transmitting data, information, signals, and so forth. For example, the control system 907 may include an interface with various input and output connectors. In some embodiments, the control system 907 may be configured to generate and provide a report to a user. Hence, in some embodiments, the control system 907 may include one or more display for providing a report to the user, for instance, via one or more graphical user interface (GUI). The report may be in any form (e.g., graphics, graph, table, image, listing, and so, forth) and include any signals, data, and information. For example, the report may display received and/or conditioned signals obtained by the monitoring hardware 905.

Various components of the electromagnetic pump system 900 may be connected or connectable by way of a communication network 911. The communication network 911 may include various components, hardware, wiring, and so forth, for facilitating exchange of signals, data, and information between the components of the electromagnetic pump system 900, via wired and/or wireless communication.

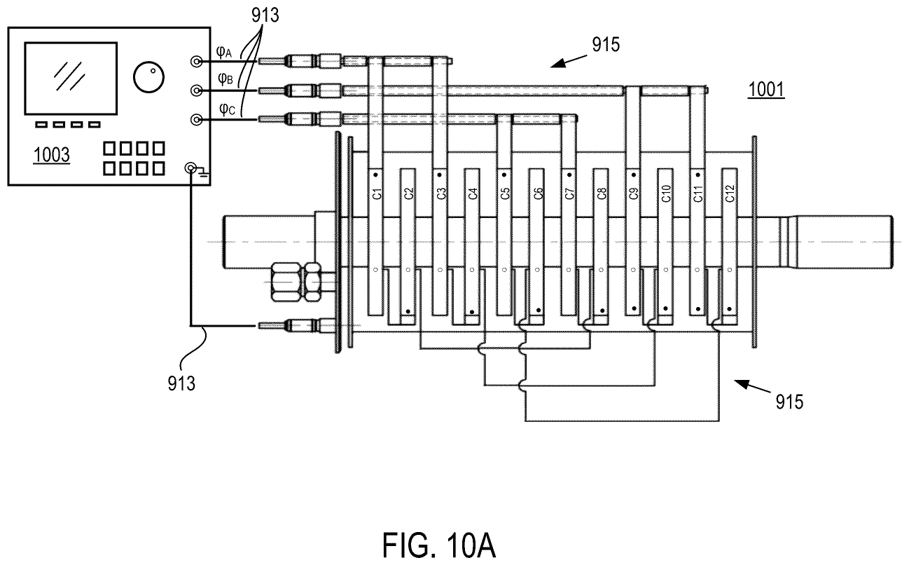

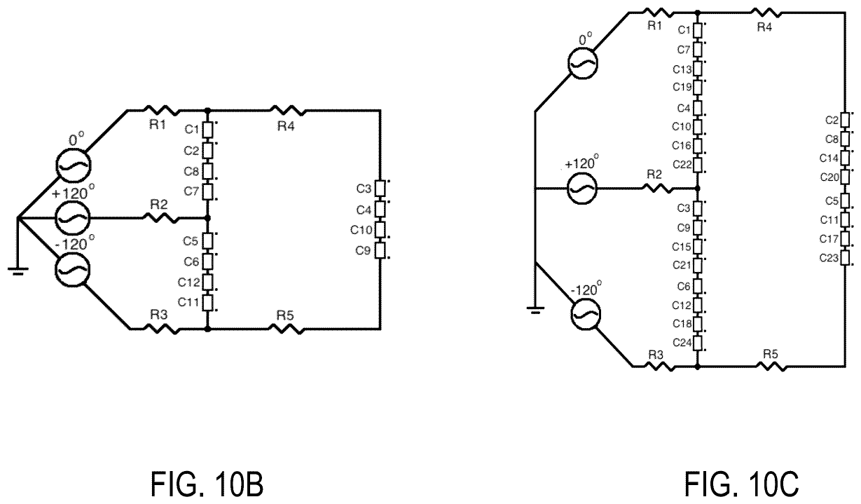

For instance, FIG. 10A illustrates an example of an electromagnetic pump 1001 connected or connectable to a power source 1003 via a number of electrical conduits 913. In some embodiments, the power source 1003 may be configured to provide one or more time-varying power signal with one or more predefined phase. For example, the power source 1003 may output a first time-varying power signal with a first phase PA via a first channel, a second time-varying power signal with a second phase φ_{B} via a second channel, and a third time-varying power signal with a third phase φ_{C} via a third channel.

The electrical conduits 913 may be connected or connectable to a number coil units (e.g., C1-C12 in FIG. 10A) of a coil assembly. In some embodiments, the coil units may be connected in a three-phase winding arrangement using a wiring assembly 915, where the wiring assembly 915 may include various electrical connections (e.g., conducting wires, conducting rods, conducting bars, conducting plates, conducting straps, conducting clamps conducting braids, and so forth). As illustrated in FIG. 10A, each coil unit of the coil assembly may be electrically connected on the outer diameter (indicated by a filled-in circular symbol “⋅” in FIG. 10A), and on the inner diameter (indicated by a non-filled circular symbol “∘” in FIG. 10A). For example, the outer diameter of coil unit “C1” may be electrically connected to the first channel (e.g., electrical conduit 913 providing the first phase φ_{A}), and the inner diameter of coil unit “C1” may be electrically connected to the outer diameter of coil unit “C2,” and so forth.

FIG. 10B illustrates an example electrical diagram illustrating electrical connectivity of coil units C1-C12 of FIG. 10A. As shown in FIG. 10B, coil units C1-C12 may be connected using a delta configuration. Other configurations may be possible. In some embodiments, the power source 1003 may be operated to provide power in an AA ZZ BB XX CC YY sequence, where A, B, C represent a balanced three-phase winding arrangement, and X, Y, Z, represent an opposite phase For example, for phases A:0°, B:120° and C:240°, phases may be X:180°, Y:300° and Z:60°. While FIGS. 10A and 10B illustrate an example coil assembly with 12 coil units, the number of coil units may vary. For instance, FIG. 10C illustrates another example electrical diagram depicting electrical connectivity of 24 coil units (i.e., coil units C1-C24).

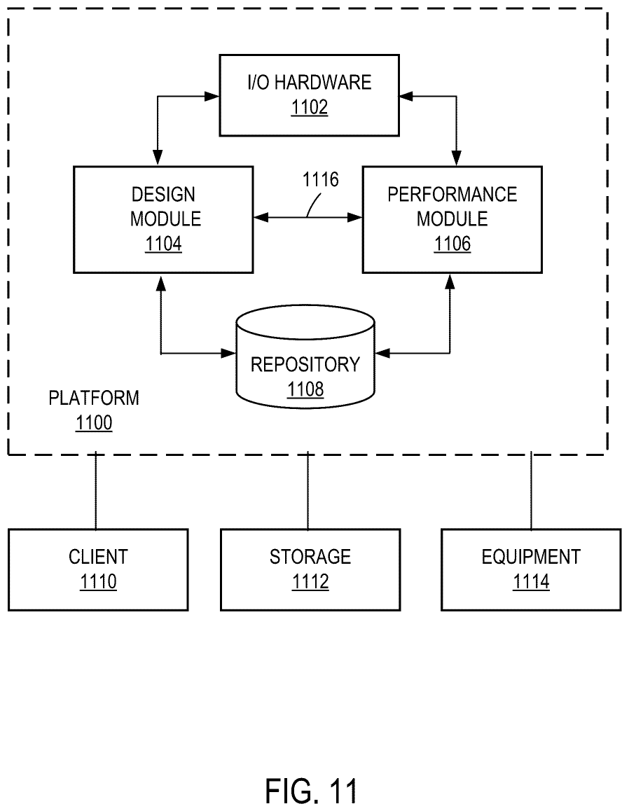

Turning to FIG. 11, a schematic diagram of an example integrated platform 1100, according to aspects of the present disclosure, is illustrated. The integrated platform 1100 may include and/or be operated using various systems, devices, hardware, and so forth, such as one or more personal computer, laptop, tablet, mainframe, server, processor, controller, and so forth, using various software, firmware, executable instructions, and so forth. As illustrated in FIG. 11, in some embodiments, the integrated platform 1100 may include various input/output (I/O) hardware 1102, a design module 1104, a performance module 1106, as well as a repository 1108, as illustrated in FIG. 11.

In particular, the I/O hardware 1102 may include various input elements and devices. For example, the I/O hardware 1102 may include a keyboard, mouse, touchscreen, as well as any other user interface, capable of registering various input, for instance, as provided by a user. The I/O hardware 104 may also include various output elements and devices capable of communicating various data and information to a user, such as a display, digital screen, touchscreen, and so forth, as well as to various other devices, systems, and so forth. In some implementations, the I/O hardware 104 may communicate various data and information to an external client 1110, a storage 1112, equipment 1114, or a combination thereof, for instance, via one or more communication networks (e.g., wired, wireless, and so forth).

The design module 1104 may be configured to carry out various steps associated with designing an electromagnetic pump, electromagnetic pump system, and/or component therein in accordance with the present disclosure. For instance, in some embodiments, the design module 1104 may interact with input elements of the I/O hardware 1102 to receive various data, information, selection, and/or instruction from a user. For example, the design module 1104 may receive as input from a user various electromagnetic pump parameters, such as geometrical parameters (e.g., dimension, angle, and so forth), material parameters (e.g., material type, and so forth), configurational parameters (e.g., number of coils in a coil assembly, number of turns for coils in the coil assembly, number of stator units in a stator assembly, number of laminations, and so forth), operational parameters (e.g., temperature of conducting fluid, frequency of power source, amplitude of power source, phase of power source, flow rate of cooling fluid, flow rate of conducting fluid, and so forth), or any combination thereof. The design module 1104 may also interact with the repository 1108 (e.g., a memory, a database, and so forth) to access such data, information, selections, and/or instructions stored therein.

The performance module 1106 may be configured to carry out various steps associated with determining and optimizing design and/or performance of an electromagnetic pump, electromagnetic pump system, and/or components therein, in accordance with the present disclosure. To this end, the performance module 1106 may be configured to carry out various computations, analyses, and/or simulations that may utilize various modeling (e.g., structural modeling, flow modeling, thermal modeling, electromagnetic modeling, multi-physics modeling, magnetohydrodynamics modeling, and so forth) and provide various outputs indicative of performance. For example, the performance module 1106 may be configured to perform a structural analysis (e.g., stress, strain, and so forth), a thermal analysis (e.g., temperature profile, temperature distribution, etc.), a magnetic field analysis (e.g., magnetic field profile, magnetic field distribution, etc.), a flow analysis (e.g., pressure profile, pressure distribution, etc.) and so forth, corresponding to various components or functions an electromagnetic pump, according to aspects of the present disclosure. Computations, analyses, and/or simulations may provide various information, renderings, outputs, metrics, and other indications of desirable and/or undesirable aspects, properties, or conditions, such as magnetic fields, induced currents, Lorentz forces, current, voltage, power consumption, fluid flow (e.g., rate, velocity, pressure), heat transfer, temperature distribution, and so forth.

By way of example, the performance module 1106 may utilize a finite element method solver that may convert partial differential equations (PDEs) into a set of equations based on meshing and physics. If a solution does not converge using a fully coupled approach, governing equations may be divided into two groups: magnetic vector potential and currents, and flow parameters (velocity, pressure, and turbulence variables). Such segregated approach solves these groups sequentially, feeding solutions from one to another until two consecutive iterations produce sufficiently similar results. By way of example, an absolute tolerance may be less than 5e-4 and relative tolerance may be less than 0.01.

In some embodiments, a model utilized by the performance module 1106 may employ a full assembly of an electromagnetic pump, for instance, by modeling connection with a pipe (e.g., loop), whereby conducting fluid travels through the electromagnetic pump, and couples electromagnetic and turbulent fluid dynamics to simulate flow in a closed system. A modelling approach utilized by the performance module 1106 may indicate, for instance, any presence of low-frequency (LF) and/or double-frequency (DF) instabilities, which may lead to complex pressure patterns at the inlet and outlet, and reduced performance. In some embodiments, a power source may be modeled as a voltage source. In other embodiments, a power source may be modeled as a current source to accelerate computational time.

In some embodiments, the design module 1104 and/or performance module 1106 may implemented as one or more processors or processing units configured (e.g., via programming and/hardwired instructions) to carry out steps, as described herein. Alternatively, or additionally, in some embodiments, the design module 1104 and/or performance module 1106 may be implemented as software, firmware, executable instructions, and so forth. For instance, in some embodiments, the design module 1104 and/or performance module 1106 may be implemented in one or more non-transitory computer-readable medium on one or more computing systems or devices, the computer-readable medium having instructions that when executed by one or more processors, cause the one or more processors to perform operations, as described herein.

As illustrated in FIG. 11, the design module 1104 may communicate with the performance module 1106 using a dynamic data link 1116. In some embodiments, the dynamic data link 1116 may include a data pipeline implementable using various software, firmware, and/or executable instructions. For instance, the data pipeline may include a data pipeline architecture configured for selectively transferring data between the design module 1104 and the performance module 1106, for instance, based on various conditions being met. In some embodiments, the dynamic data link 1116 may include various hardware (e.g., controller, processor, hardwire connection, and so forth) configured to link the design module 1104 and performance module 1106 and aid in transferring data and information (e.g., renderings, models, electromagnetic pump parameters, and other inputs and outputs) therebetween.

Selective transfer of data and information between the design module 1104 and the performance module 1106 may be performed via dynamic data link 1116. For instance, in some implementations, data and information transfer may be carried out subject to user input (e.g., of one or more electromagnetic pump parameter), selection (e.g., of computation, analysis, or simulation desired), or command (e.g., initiating a computation, analysis, or simulation desired). In other implementations, data and information transfer may be carried out subject to one or more predetermined conditions being satisfied. In one example, entry of a predetermined set of electromagnetic pump parameters in a GUI (e.g., generated using the design module 1104) may trigger a transfer of one or more outputs (e.g., electromagnetic pump parameters), to be used to initiate and carry out various computations, analyses or simulations (i.e., carried out using the performance module 1106), as described. In this example, the predetermined set of electronic pump parameters may include parameters sufficient to carry one or more computer, analysis, or simulation, as desired. In another example, entry of one or more new or modified electromagnetic pump parameters in a GUI may trigger a transfer of one or more outputs (e.g., new or modified electromagnetic pump parameters), to be used to initiate and carry out various computations, analyses, or simulations, as described.

In some implementations, the performance module 1106 may also transfer data and information (e.g., generated via computation, analysis, or simulation) to the design module 1104 using the dynamic data link 1116. The transferred data and information may be presented, for example, in a GUI generated using the design module 1104. The transfer data and information may also be used to modify various inputs to the design module 1104. Such inputs may be used to generate or modify various renderings, models, electromagnetic pump parameters, and so forth. In some implementations, data and information transferred to the design module 1104 from the performance module 1106 may be used to inform, as well as constrain various inputs to the design module 1104, such as various electromagnetic pump parameters or parameter modifications.

In this manner, an iterative optimization process may be carried out by the design module 1104, the performance module 1106, or another processor or processing unit, whereby, for instance, a set of electromagnetic pump parameter values may be narrowed to optimize design and performance of an electromagnetic pump, in accordance with embodiments described herein. In some implementations, the iterative optimization process may be carried out until, for instance, when one or more pump performance metric reaches a predetermined value, falls within a predetermined tolerance of the predetermined value, and/or falls within a predetermined range of values. To this end, at least one pump performance metric may be computed, and compared to a reference (e.g., stored in the repository 1108, storage 1112, a memory, or other data storage location).

In some embodiments, the design module 1104, the performance module 1106, or another processor or processing unit, may interact with various output elements of the I/O hardware 104 to generate and provide various data and information, for example, in the form of a report. The report may be in any form and include any data and information, and may be generated and/or provided continuously, intermittently, or subject to one or more predetermined condition.

For example, in some implementations, the design module 1104, performance module 1106, or another processor or processing unit may interact with output elements of the I/O) hardware 104 to generate and provide data, information, and/or instructions to a user, for example, in a GUI. For instance, the design module 1104 may be configured to generate (e.g., on a display) a GUI illustrating, for example, a one-dimensional, a two-dimensional, and/or three-dimensional rendering or model of an electromagnetic pump, an electromagnetic pump system, and/or various components therein, designed and optimized as described, as well as various corresponding data or information. In some implementations, the design module 1104, the performance module 1106, or another processor or processing unit may generate a report providing instructions for operating and/or producing at least one component of the electromagnetic pump, in accordance with embodiments described herein. For example, the report may be in the form of one or more file, such as computer-aided design (CAD) file, computer-aided manufacturing (CAM) file, FBX file, OBJ file, STL file, 3MF file, PLY file, G-Code file, X3G file, AMF file, VRML and others.

As illustrated in FIG. 11, the report may be communicated to an external client 1110, as well as communicated to the storage 1112, for instance, for storage therein. The report may also be communicated to various equipment 1114, such as manufacturing equipment configured to produce at least one component of the electromagnetic pump (e.g., an additive manufacturing system or apparatus), operational equipment configured to operate at least one component of the electromagnetic pump (e.g., hardware or equipment described with reference to the system 900). Responsive to the report (e.g., instructions, data, or other information there), the equipment 1114 may carry various tasks, such as tasks related to operating and/or producing one or more components on the electromagnetic pump.

As appreciated from description herein, the integrated platform 1110 provides improved efficiency in the process of electromagnet pump design and performance. Among several advancements, the integrated platform 1110 allows for dynamic transfer of data and information between the design module 1104 and performance module 1106 via the dynamic data link 1116. In this manner, performance effects of designs and design modifications may be performed and assessed in parallel, and in real-time, thereby allowing for efficient optimization of various components of an electromagnetic pump, according to embodiments described herein.

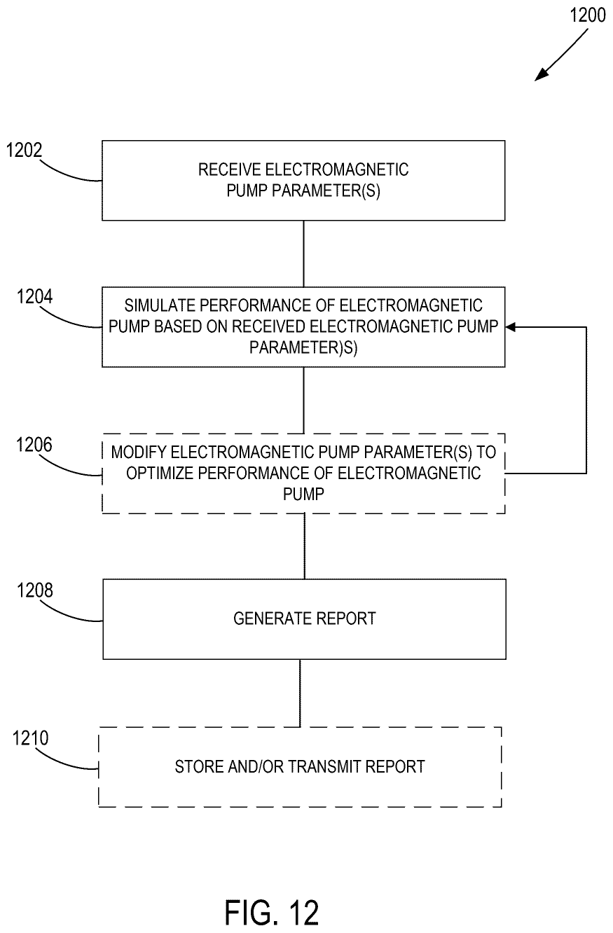

Turning now to FIG. 12, a flowchart setting forth steps of a process 12 for optimizing e, according to aspects of the present disclosure, is illustrated. Steps of the process 1100 may be carried out using any suitable devices, tools, hardware, systems, and so forth. In some implementations, the process 1200 may be carried out using an integrated platform, as described with reference to FIG. 11. Although the process 1200 is illustrated and described as a sequence of steps, it is contemplated that the steps may be produced in any order or combination, need not include all illustrated steps, and may include additional steps.

The process 1200 may begin at process block 1202 with receiving one or more electronic pump parameters for an electromagnetic pump for moving conducting fluid. In some implementations, the electromagnetic pump parameter(s) may be received by design module of an integrated platform operated using a computing system, as described. For instance, the electronic pump parameter(s) may be provided by a user as input. In one non-limiting example, the electronic pump parameter(s) may be provided by the user in a GUI generated using the design module, where the GUI is configured to receive data entry or a selection of one or more electromagnetic pump parameters from. Alternatively, or additionally, one or more electronic pump parameters may be accessed from a data storage location or repository.

As described, received electromagnetic pump parameter(s) may be used generate and provide data, information, and/or instructions to a user, for example, in a GUI. For instance, a design module may generate a GUI providing various renderings or models of an electromagnetic pump, an electromagnetic pump system, and/or various components therein, as well as various corresponding data or information. For instance, the design module may generate a rendering of the electromagnetic pump on the GUI based at least on data entry or selection of electromagnetic pump parameters from the user.

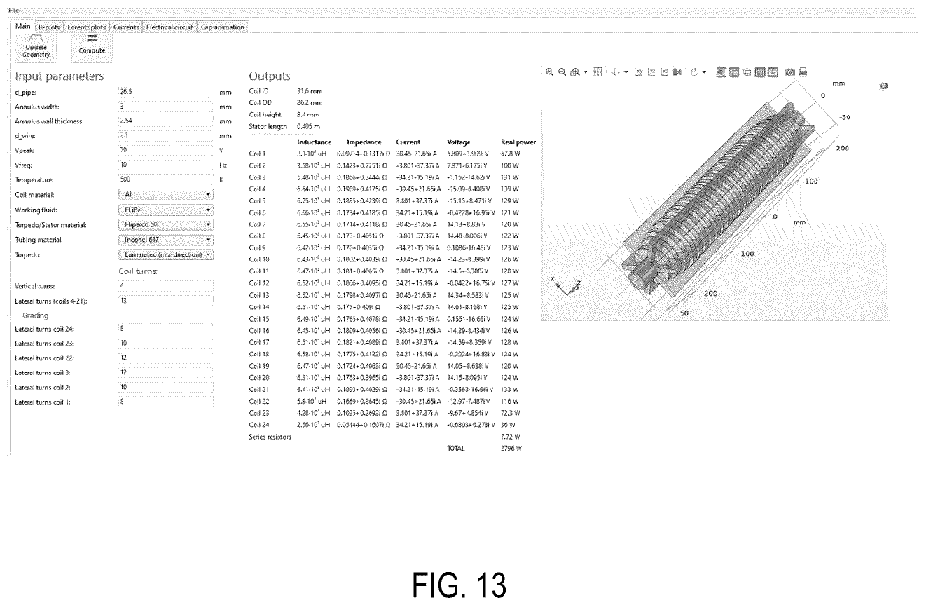

For instance, FIG. 13 shows a non-liming example of GUI depicting a 3D model of an electromagnetic pump with 24 coil units, according to embodiments described herein, along with various input parameters and outputs corresponding to components on the electromagnetic pump in data fields, image fields, menus, tabs, and so forth. For instance, in the GUI shown, a user may input or select various dimensions, configurations, conditions, and materials of various components of the electromagnetic pump (e.g., hollow duct, core, coil assembly, stator assembly, and so forth). Also, the GUI provides for various data entry, selections (e.g., “Update Geometry,” “Compute”, and so forth), which may initiate various actions such as computations, analyses, or simulations, as described.

Referring again to FIG. 12, a performance of an electromagnetic pump, electromagnetic pump system, and/or component thereof, may be simulated based on received electromagnetic pump parameters, as indicated by process block 1204. In some implementations, the performance may be simulated using a performance module of an integrated platform, as described. To this end, various data and information, (e.g., renderings, models, electromagnetic pump parameters, and other inputs and outputs) used to simulate performance of the electromagnetic pump, electromagnetic pump system, and/or component thereof, may be transferred from a design module of the integrated platform using a dynamic data link.

As described, the dynamic data link may include a data pipeline, and/or various hardware configured to link a design module and performance module, and aid in transferring data and information therebetween. In some implementations, data and information may be selectively transferred, for instance, subject to user input (e.g., of one or more electromagnetic pump parameter), user selection (e.g., of computation, analysis, or simulation desired), or user command (e.g., initiating a computation, analysis, or simulation desired). In other implementations, data and information may be selectively transferred subject to one or more predetermined conditions being satisfied. In one example, entry of a predetermined set of electromagnetic pump parameters in a GUI (e.g., generated using the design module) may trigger a transfer of one or more outputs (e.g., electromagnetic pump parameters), to be used to initiate and carry out various computations, analyses or simulations (i.e., carried out using the performance module), as described. In this example, the predetermined set of electronic pump parameters may include parameters sufficient to carry one or more computer, analysis, or simulation, as desired. In another example, entry of one or more new or modified electromagnetic pump parameters in a GUI may trigger a transfer of one or more outputs (e.g., new or modified electromagnetic pump parameters), to be used to initiate and carry out various computations, analyses, or simulations, as described.

Any number of simulations may be carried at process block 1204 to determine performance. By way of example, performance may be determined by carrying out a simulation of flow of conducting fluid in the electromagnetic pump, a simulation of magnetic field or magnetic flux in the electromagnetic pump, a simulation of temperature in the electromagnetic pump, a simulation of stress, strain, and so forth, in the electromagnetic pump, or any combination thereof. Any data and information may be generated in simulating the performance at process block 1204. In some implementations, one or more pump performance metric may be computed or result from simulation(s) at process block 1204. By way of example, computed pump performance metric(s) may include various values, profiles, distributions, and so forth, or temperature, pressure, flow, shear, strain, magnetic field, magnetic flux, current, voltage, and so forth. In some implementations, any number of pump performance metric(s) may be associated with specific components of an electromagnetic pump or electromagnetic pump system, according to embodiments described herein.

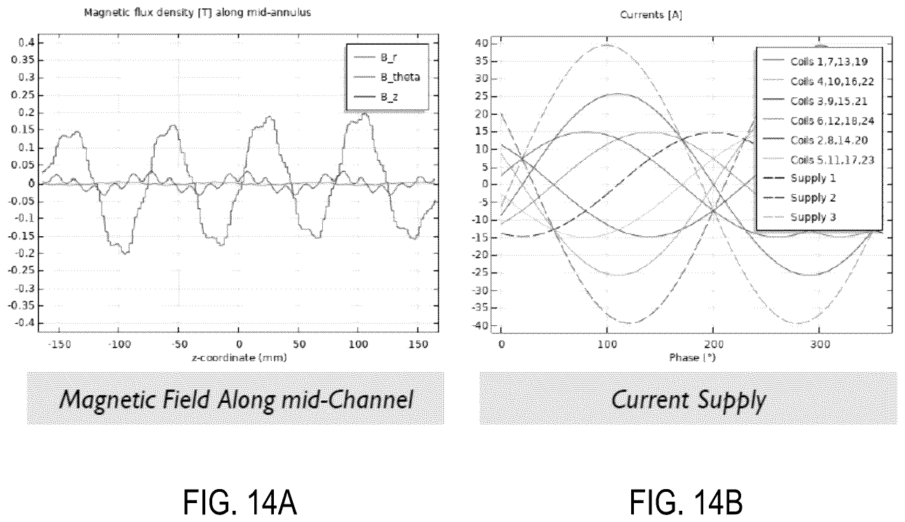

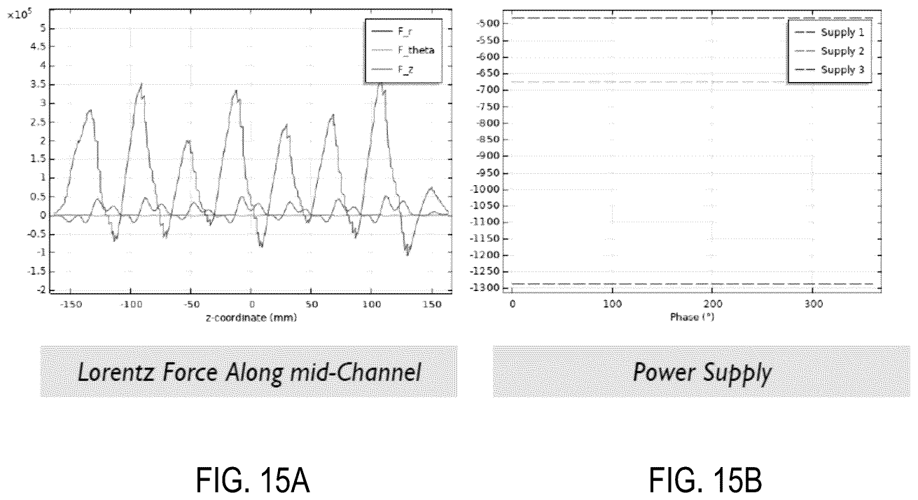

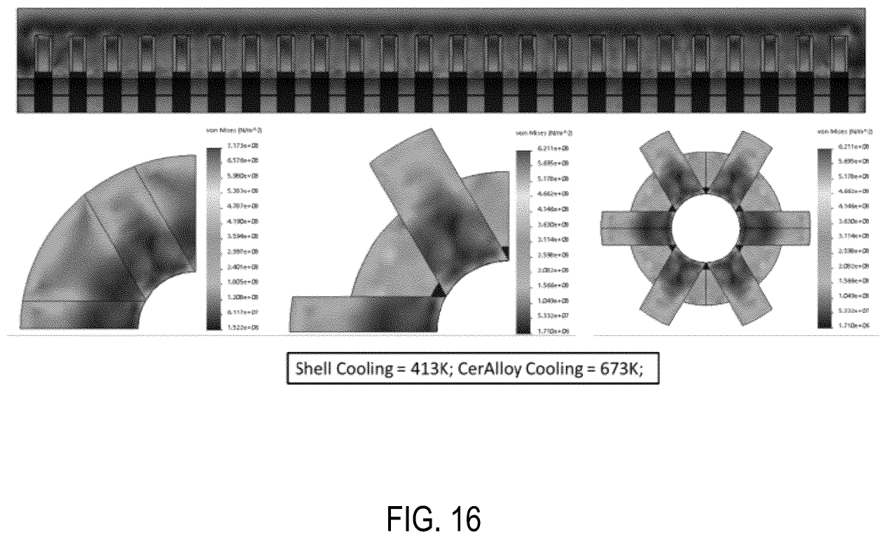

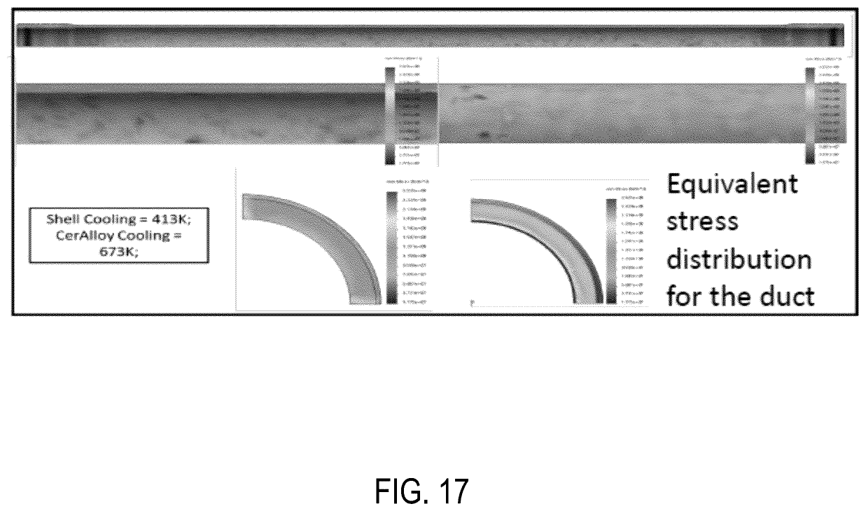

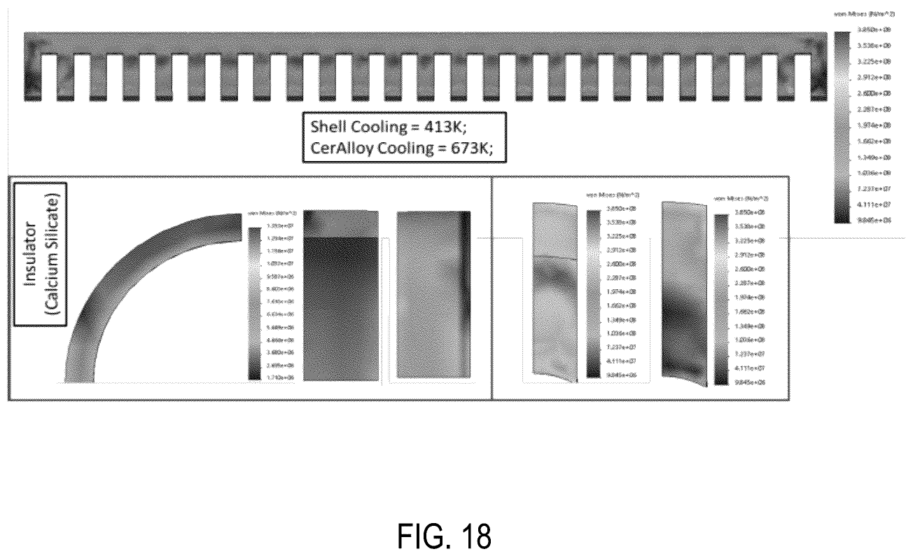

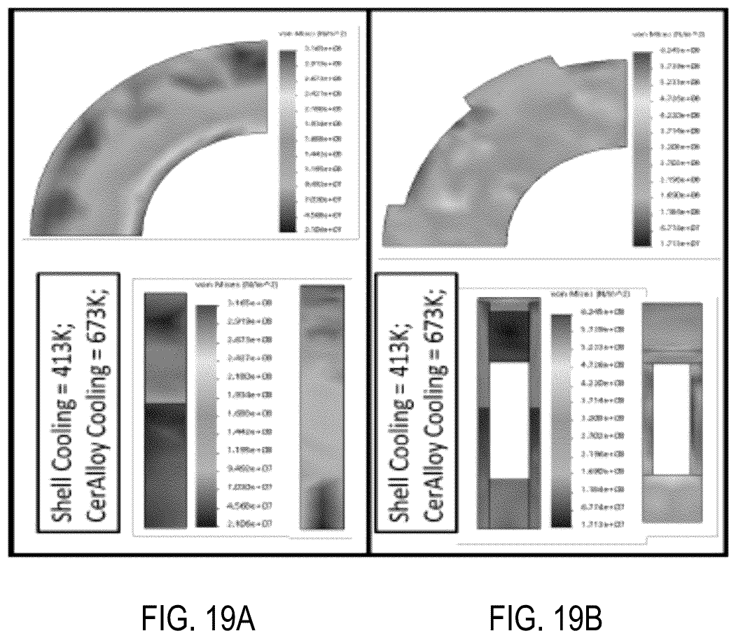

By way example, FIGS. 14A-19B provide non-limiting examples of simulation results, in accordance with aspects of the present disclosure. Specifically, FIG. 14A is a graph showing magnetic field as a function of a coordinate for an example electromagnetic pump. FIG. 14B shows a graph from simulation of current as a function of phase for various coil units on an example electromagnetic pump. FIG. 15A is a graph showing Lorentz force as a function of a coordinate of an example electromagnetic pump. FIG. 15B is a graph showing power as a function of phase for an example electromagnetic pump. FIG. 16 is an illustration showing temperature distribution for a stator unit and coil unit on an example electromagnetic pump, in accordance embodiments described herein. FIG. 17 is an illustration shown stress distribution for a hollow duct on an example electromagnetic pump, in accordance embodiments described herein. FIG. 18 is another illustration showing temperature distribution for a hollow duct and stator unit on an example electromagnetic pump, in accordance embodiments described herein FIG. 19A is yet another illustration showing temperature distribution of cooling unit on an example electromagnetic pump, in accordance with embodiments described herein. FIG. 19B is yet another illustration showing temperature distribution of another cooling unit on an example electromagnetic pump, in accordance with embodiments described herein.

Referring again to FIG. 12, based on the performance simulated at process block 1204, one or more electromagnetic pump parameters may be modified to optimize performance of the electromagnetic pump, electromagnetic pump system, and/or component thereof, as illustrated by process block 1206. In some implementations, a user may modify one or more electromagnetic pump parameters, for instance, by providing input (e.g., data entry, selection, and so forth), in a GUI generated by a design module, as described.

In other implementations, modifications may be performed automatically based on results from various simulations carried out at process block 1204. To this end, data and information (e.g., generated via computation, analysis, or simulation) may be automatically transferred to the design module using the dynamic data link. The transferred data and information may be presented, for example, in a GUI generated using the design module. The transfer data and information may also be used to modify various inputs to the design module. Such inputs may be used to generate or modify various renderings, models, electromagnetic pump parameters, and so forth. In some implementations, data and information transferred to the design module from the performance module may be used to inform, as well as constrain various inputs to the design module, such as various electromagnetic pump parameters or parameter modifications.

Steps 1204 and 1206 may be performed a number of times. In this manner, an iterative optimization process may be carried out, such that a set of electromagnetic pump parameter values may be narrowed to optimize design and performance of an electromagnetic pump, electromagnetic pump system, and/or components thereof, in accordance with embodiments described herein. In some implementations, the iterative optimization process may be carried out until, for instance, when one or more pump performance metric reaches a predetermined value, falls within a predetermined tolerance of the predetermined value, and/or falls within a predetermined range of values. To this end, at least one pump performance metric computed may be compared to a reference (e.g., stored in a repository, storage, memory, and so forth).

In some implementations, a report may also be generated and provided at process block 1208. The report may be in any form and provide any information. For example, the report may include data, information, and/or instructions to a user, for example, in a GUI. For instance, the report may include a one-dimensional, a two-dimensional, and/or three-dimensional rendering or model of an electromagnetic pump, an electromagnetic pump system, and/or various components therein, designed and optimized as described, as well as various corresponding data or information. The report may also include results of various simulations, including various pump performance metrics, as described. In some implementations, the report may include machine-readable and/or executable instructions. As described, when executed by a device, apparatus, system, processor, controller, and so forth, the instructions may cause various equipment to operate and/or produce at least one component of the electromagnetic pump, in accordance with embodiments described herein. For example, as described, the instructions may be executed by manufacturing equipment, such as an additive manufacturing system, configured to produce various components of an electromagnetic pump, or electromagnetic pump system, as described.

The report generated at step 1208 may be provided using any system, device, or apparatus. For example, in some implementations, report may be provided using a display. As indicated by process block 1210, in some implementations, the report may be stored in a storage location, such as a memory, database, and so forth, as well transmitted to a remote device, system, apparatus, server, equipment, and so forth. The report may be generated, provided, and/or transmitted continuously (e.g., substantially real-time), intermittently (e.g., at a predefined period), as well as subject to satisfying a reporting condition.

One or more elements or aspects or steps, or any portion(s) thereof, from one or more of any of claims herein can be combined with one or more elements or aspects or steps, or any portion(s) thereof, from one or more of any of the other claims or combinations thereof, to form one or more additional implementations and/or claims of the present disclosure.

While various examples of the present disclosure have been described above, such examples are presented for purposes of illustration, and not limitation. Numerous changes to the disclosed examples can be made in accordance with the disclosure herein without departing from the spirit or scope of the disclosure. Thus, the breadth and scope of the present disclosure should not be limited by any of the above-described examples. Rather, the scope of the disclosure should be defined in accordance with the following claims and their equivalents.

Although the disclosure has been illustrated and described with respect to one or more implementations, equivalent alterations and modifications will occur to others skilled in the art upon the reading and understanding of this specification and the annexed drawings. In addition, while a particular feature of the disclosure may have been disclosed with respect to only one of several implementations, such feature may be combined with one or more other features of the other implementations as may be desired and advantageous for any given or particular application.

The terminology used herein is for the purpose of describing particular examples only and is not intended to be limiting of the disclosure. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this disclosure belongs. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

What is claimed is:

1. A method for optimizing an electromagnetic pump for moving conducting fluid, the method comprising:
receiving, by a design module of an integrated platform operated using a computing system, electromagnetic pump parameters corresponding to an electromagnetic pump for moving conducting fluid;
simulating, using a performance module of the integrated platform, a performance of the electromagnetic pump based on electromagnetic pump parameters received on the design module;
modifying the electromagnetic pump parameters to optimize the electromagnetic pump; and
generating and transmitting, using the integrated platform, instructions for producing at least one component of the electromagnetic pump based on modified electromagnetic pump parameters.

2. The method of claim 1, wherein the method further comprises generating, using the design module of the integrated platform, a graphical user interface configured to receive a selection of electromagnetic pump parameters from a user.

3. The method of claim 2, wherein the method further comprises generating, using the design module of the integrated platform, a rendering of the electromagnetic pump on the graphical user interface based at least on the selection of electromagnetic pump parameters from the user.

4. The method of claim 1, wherein the method further comprises transferring electromagnetic pump parameters received by the design module to the performance module of the integrated platform using a dynamic data link.

5. The method of claim 4, wherein the method further comprises simulating, using the performance module, flow of conducting fluid in the electromagnetic pump by performing a flow analysis based at least on electromagnetic pump parameters transferred using the dynamic data link.

6. The method of claim 4, wherein the method further comprises simulating, using the performance module, magnetic field or magnetic flux in the electromagnetic pump by performing a magnetic field analysis based at least on electromagnetic pump parameters transferred using the dynamic data link.

7. The method of claim 4, wherein the method further comprises simulating, using the performance module, temperature in the electromagnetic pump by performing a thermal analysis based at least on electromagnetic pump parameters transferred using the dynamic data link.

8. The method of claim 4, wherein the method further comprises simulating, using the performance module, stress, strain, or both, in the electromagnetic pump by performing a structural analysis based at least on electromagnetic pump parameters transferred using the dynamic data link.

9. The method of claim 1, wherein the method further comprises optimizing a performance of the electromagnetic pump by computing at least one pump performance metric and comparing at least one pump performance metric to a reference.

10. The method of claim 1, wherein the method further comprises generating instructions executable by manufacturing equipment to produce at least one component of the electromagnetic pump.

11. The method of claim 11, wherein the method further comprises generating instructions executable by an additive manufacturing system.

12. A non-transitory computer-readable medium for optimizing an electromagnetic pump for moving conducting fluid, the computer-readable medium having instructions stored thereon, the instructions, when executed by one or more processors, cause the one or more processors to perform operations comprising:
receiving, by a design module of an integrated platform operated using a computing device, electromagnetic pump parameters corresponding to an electromagnetic pump for moving conducting fluid;
simulating, using a performance module of the integrated platform, a performance of the electromagnetic pump based on electromagnetic pump parameters received on the design module;
modifying the electromagnetic pump parameters to optimize the performance of the electromagnetic pump; and
generating and transmitting, using the integrated platform, instructions for producing at least one component of the electromagnetic pump based on modified electromagnetic pump parameters.

13. The non-transitory computer-readable medium of claim 12, wherein the instructions further cause the one or more processor to perform operations to generate, using the design module of the integrated platform, a graphical user interface configured to receive a selection of electromagnetic pump parameters from a user.

14. The non-transitory computer-readable medium of claim 13, wherein the instructions further cause the one or more processor to perform operations to generate, using the design module of the integrated platform, a rendering of the electromagnetic pump on the graphical user interface based at least on the selection of electromagnetic pump parameters from the user.

15. The non-transitory computer-readable medium of claim 12, wherein the instructions further cause the one or more processor to perform operations to transfer electromagnetic pump parameters received by the design module to the performance module of the integrated platform using a dynamic data link.

16. The non-transitory computer-readable medium of claim 15, wherein the instructions further cause the one or more processor to perform operations to simulate, using the performance module, a:
(i) flow of conducting fluid in the electromagnetic pump by performing a flow analysis based at least on electromagnetic pump parameters transferred using the dynamic data link;
(ii) magnetic field or magnetic flux in the electromagnetic pump by performing a magnetic field analysis based at least on electromagnetic pump parameters transferred using the dynamic data link;
(iii) temperature in the electromagnetic pump by performing a thermal analysis based at least on electromagnetic pump parameters transferred using the dynamic data link;
(iv) stress, strain, or both, in the electromagnetic pump by performing a structural analysis based at least on electromagnetic pump parameters transferred using the dynamic data link; or
(v) combination of (i), (ii), (iii), and (iv).

17. The non-transitory computer-readable medium of claim 12, wherein the instructions further cause the one or more processor to perform operations to optimize a performance of the electromagnetic pump by computing at least one pump performance metric and comparing at least one pump performance metric to a reference.

18. The non-transitory computer-readable medium of claim 12, wherein the instructions further cause the one or more processor to perform operations to generate instructions executable by manufacturing equipment to produce at least one component of the electromagnetic pump.

19. The non-transitory computer-readable medium of claim 12, wherein the instructions further cause the one or more processor to perform operations to generate instructions executable by an additive manufacturing system.

20. An integrated platform for optimizing an electromagnetic pump for moving conducting fluid, the integrated platform operated using a computing system comprising:
a design module configured to generate a rendering of an electromagnetic pump;
a performance module, in communication with the design module, configured to simulate a performance of the electromagnetic pump;
a dynamic data link configured to selectively transfer one or more electromagnetic pump parameter from the design module to the performance module, the performance module simulating the performance of the electromagnetic pump using the one or more electromagnetic pump parameter transferred;
a processor configured to execute steps to:
modify, based on the performance, at least one electromagnetic pump parameter to optimize the electromagnetic pump, and
generate instructions for producing at least one component of the electromagnetic pump based on the at least one electromagnetic pump parameter modified.
